(19) United States
(12) Patent Application Publication
(10) Pub. No.: US 2026/0005197 A1
(43) Pub. Date: Jan. 1, 2026

(54) SEMICONDUCTOR DEVICE, INSULATION SWITCH, AND RECTIFIER CHIP

(71) Applicant: ROHM CO., LTD., Kyoto (JP)

(72) Inventor: Junichi SEKITO, Kyoto (JP)

(21) Appl. No.: 19/244,385

(22) Filed: Jun. 20, 2025

(30) Foreign Application Priority Data
Jun. 28, 2024 (JP) 2024-105405

(51) Int. Cl. H01L 25/065; H01L 23/00; H01L 23/495; H10D 80/20

(52) U.S. Cl. CPC H01L 25/0655; H01L 23/49513; H01L 23/49537; H01L 24/48; H10D 80/211; H10D 80/231; H01L 24/32; H01L 24/73; H01L 2224/32245; H01L 2224/48149; H01L 2224/48245; H01L 2224/73265; H01L 2924/14252

(57) ABSTRACT

A semiconductor device includes: a first transformer; a second transformer; a first rectifier chip; a second rectifier chip; and a first frame. Each of the first rectifier chip and the second rectifier chip includes: a first output pad and a second output pad; a semiconductor substrate of a first conductivity type including a first surface; a first semiconductor region of a second conductivity type disposed on the first surface; a first transistor provided in the first semiconductor region and electrically connected to the first output pad; and a second semiconductor region of the second conductivity type provided at a position spaced apart from the first transistor in the first semiconductor region and electrically connected to the second output pad. The second semiconductor region is in contact with the semiconductor substrate. The first rectifier chip and the second rectifier chip are disposed to be spaced apart from each other.

### CROSS-REFERENCE TO RELATED APPLICATION

The present invention claims priority under 35 U.S.C. § 119 to Japanese Patent Application No. 2024-105405, filed on Jun. 28, 2024, the entire contents of which are incorporated herein by reference.

### TECHNICAL FIELD

The present disclosure relates to a semiconductor device, an insulation switch, and a rectifier chip.

### BACKGROUND

Signal transmission devices that transmit signals between a primary circuit system and a secondary circuit system while electrically isolating the primary circuit system from the secondary circuit system are used in various applications such as power supply devices or motor drive devices, etc. As an example of a signal transmission device, an insulated gate driver that applies a gate voltage to a gate of a switching element such as a transistor is known.

### BRIEF DESCRIPTION OF DRAWINGS

The accompanying drawings, which are incorporated in and constitute a part of the specification, illustrate embodiments of the present disclosure.

FIG. 1 is a block circuit diagram showing a schematic configuration of an insulation switch according to a first embodiment.

FIG. 2 is a circuit diagram showing an example of the insulation switch of FIG. 1.

FIG. 3 is a waveform diagram showing an operation of the insulation switch of FIG. 2.

FIG. 4 is a schematic plan view showing an example of a semiconductor device of FIG. 2.

FIG. 5 is a schematic side view of the semiconductor device of FIG. 4.

FIG. 6 is a schematic plan view showing an enlarged portion of the semiconductor device of FIG. 4.

FIG. 7 is a schematic plan view showing an enlarged portion of the semiconductor device of FIG. 4.

FIG. 8 is a schematic perspective view showing a transformer chip of FIG. 4.

FIG. 9 is a schematic plan view of the transformer chip of FIG. 8.

FIG. 10 is a schematic plan view showing an enlarged portion of the transformer chip of FIG. 9.

FIG. 11 is a schematic plan view showing a primary coil of the transformer chip of FIG. 9.

FIG. 12 is a schematic plan view showing a secondary coil of the transformer chip of FIG. 9.

FIG. 13 is a schematic cross-sectional view of the transformer chip cut along line F13-F13 in FIG. 9.

FIG. 14 is a schematic cross-sectional view of the transformer chip cut along line F14-F14 in FIG. 9.

FIG. 15 is a schematic plan view showing a rectifier chip of FIG. 4.

FIG. 16 is a schematic cross-sectional view of the rectifier chip of FIG. 13.

FIG. 17 is an explanatory diagram showing an insulation switch according to the first embodiment.

FIG. 18 is an explanatory diagram showing an insulation switch according to a comparative example.

FIG. 19 is a block circuit diagram showing a schematic configuration of an insulation switch according to a second embodiment.

FIG. 20 is a schematic plan view showing an example of a semiconductor device of FIG. 19.

FIG. 21 is a schematic plan view showing a rectifier chip of FIG. 20.

FIG. 22 is a schematic cross-sectional view of the rectifier chip of FIG. 21.

FIG. 23 is a schematic plan view showing an enlarged portion of the semiconductor device of FIG. 19.

FIG. 24 is a schematic plan view showing a semiconductor device according to a modification.

FIG. 25 is a schematic plan view showing a semiconductor device according to a modification.

FIG. 26 is a schematic plan view showing a semiconductor device according to a modification.

FIG. 27 is a schematic plan view showing a semiconductor device according to a modification.

FIG. 28 is a schematic plan view showing a semiconductor device according to a third embodiment.

FIG. 29 is a schematic plan view showing a rectifier chip of FIG. 28.

FIG. 30 is a schematic cross-sectional view showing the rectifier chip of FIG. 29.

FIG. 31 is a schematic plan view showing a semiconductor device according to a modification.

FIG. 32 is a block diagram showing a schematic configuration of an insulation switch according to a fourth embodiment.

FIG. 33 is an explanatory diagram showing the insulation switch of FIG. 32.

FIG. 34 is a schematic plan view showing a semiconductor device according to a modification.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, some embodiments of an insulation switch according to the present disclosure will be described with reference to the accompanying drawings. It should be noted that, for simplicity and clarity of explanation, constituent elements shown in the drawings are not necessarily drawn to scale. Further, in order to facilitate understanding, hatching lines may be omitted in cross-sectional views. The accompanying drawings merely illustrate embodiments of the present disclosure and should not be considered as limiting the present disclosure. The terms such as “first,” “second,” and “third” in the present disclosure are used merely to distinguish between objects and are not intended to rank the objects.

The following detailed description includes devices, systems, and methods embodying exemplary embodiments of the present disclosure. This detailed description is for illustrative purposes only and is not intended to limit the embodiments of the present disclosure or the applications and uses of such embodiments.

The expression “at least one” as used in the present disclosure means “one or more” of desired options. As an example, when there are two options, the expression “at least one” as used in the present disclosure means “only one option” or “both of the two options.” As another example, when there are three or more options, the expression “at least one” as used in the present disclosure means “only one option” or “any combination of two or more options.”

### First Embodiment

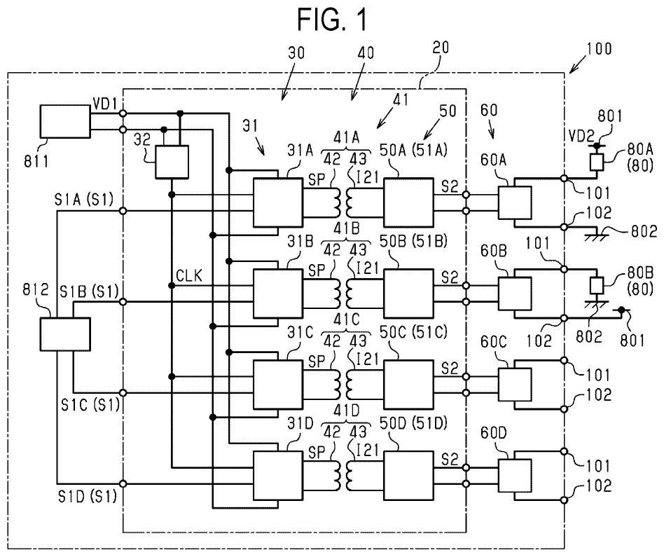

An insulation switch 100 according to a first embodiment will be described with reference to FIG. 1 to FIG. 17.

### (Schematic Configuration of Insulation Switch)

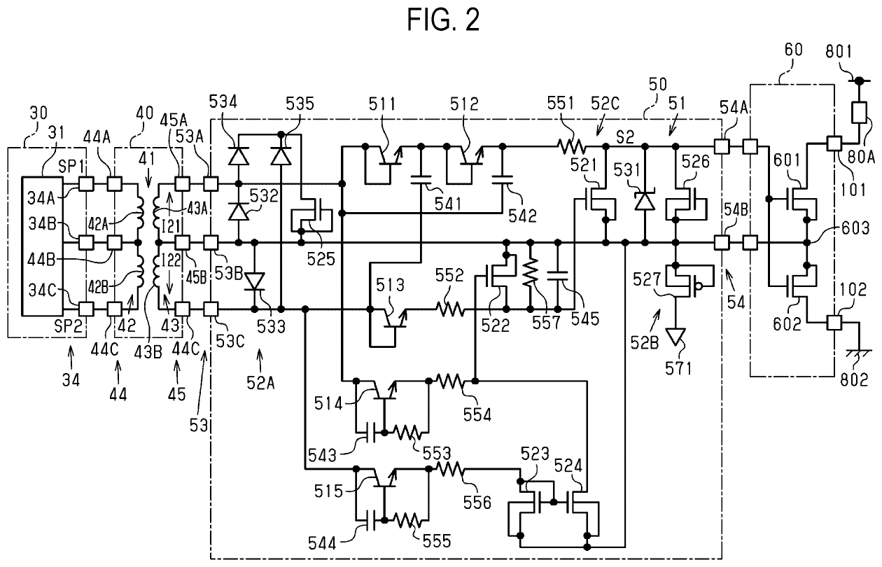

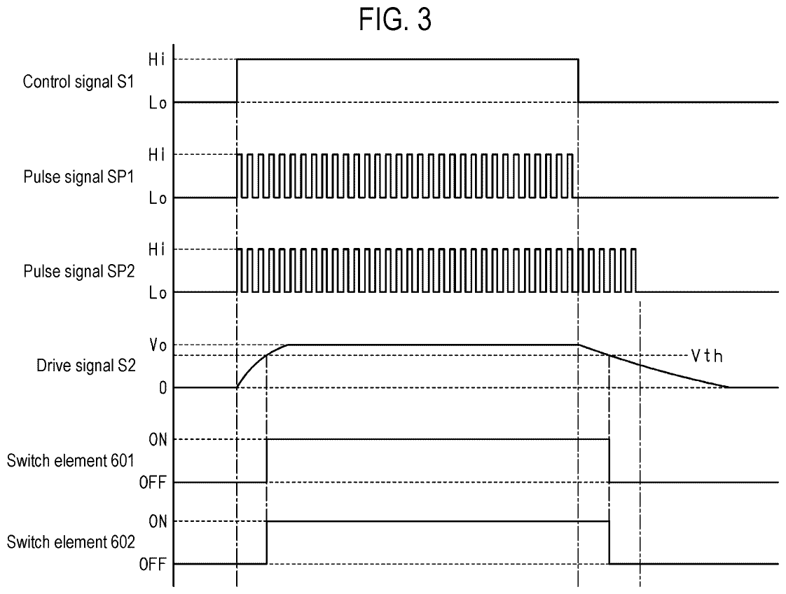

FIG. 1 is a block circuit diagram showing a schematic configuration of the insulation switch 100 according to the first embodiment. FIG. 2 is a circuit diagram showing an example of the insulation switch 100 of FIG. 1. Further, FIG. 2 shows a circuit configuration of a single switch circuit 60. FIG. 3 is a waveform diagram showing an operation of the insulation switch 100 of FIG. 2.

The insulation switch 100 shown in FIG. 1 may be mounted on a device such as a sequencer. The insulation switch 100 may be used as a switch that switches on and off a circuit that supplies a drive voltage VD2 to a load 80. In one example, the insulation switch 100 is connected to a power supply circuit 811. The power supply circuit 811 supplies an operating voltage VD1 to the insulation switch 100. In one example, the operating voltage VD1 is a DC voltage. The insulation switch 100 is connected to a control circuit 812. The control circuit 812 outputs a control signal S1 for controlling the load 80 to the insulation switch 100. The insulation switch 100 may be configured as a single unit. The single unit may be configured to include at least one of the control circuit 812 or the power supply circuit 811 together with the insulation switch 100.

The insulation switch 100 may include a plurality of switch circuits 60 and a semiconductor device 20 to which the plurality of switch circuits 60 are connected. The plurality of switch circuits 60 may have a same configuration. In FIG. 1, a first switch circuit 60A, a second switch circuit 60B, a third switch circuit 60C, and a fourth switch circuit 60D are shown as the plurality of switch circuits 60. In the following description, when the first to fourth switch circuits 60A to 60D are not distinguished from one another, the first to fourth switch circuits 60A to 60D are simply referred to as a switch circuit 60 or each switch circuit 60. Each switch circuit 60 may be configured as a bidirectional switch. The semiconductor device 20 is configured to be capable of driving each switch circuit 60 individually.

The control circuit 812 outputs a plurality of control signals S1 corresponding to the plurality of switch circuits 60. The semiconductor device 20 is configured to turn on/off the corresponding switch circuits 60 in response to the plurality of control signals S1. In one example, the control circuit 812 outputs a first control signal SIA, a second control signal S1B, a third control signal SIC, and a fourth control signal SID corresponding to the first switch circuit 60A, the second switch circuit 60B, the third switch circuit 60C, and the fourth switch circuit 60D, respectively. In the following description, when the first to fourth control signals SIA to SID are not distinguished from one another, the first to fourth control signals SIA to SID are simply referred to as a control signal S1 or each control signal S1. The semiconductor device 20 is configured to turn on/off the first to fourth switch circuits 60A to 60D in response to the first to fourth control signals SIA to SID, respectively. It can be said that the semiconductor device 20 includes a drive circuit that drives the first to fourth switch circuits 60A to 60D.

As shown in FIG. 1, the first to fourth switch circuits 60A to 60D are each connected between a first connection terminal 101 and a second connection terminal 102. The first connection terminal 101 and the second connection terminal 102 may be provided as terminals of a device including the insulation switch 100. The second connection terminal 102 may be called a common terminal, for example.

The load 80 is connected to the first connection terminal 101 or the second connection terminal 102 according to a usage mode of the load 80. In FIG. 1, a first load 80A and a second load 80B are shown as the load 80.

The first load 80A is, for example, a load driven in a sink mode. The first load 80A is connected between the first connection terminal 101 and a high potential terminal 801 that supplies the drive voltage VD2 to the first load 80A. The second connection terminal 102, which is the common terminal, is connected to a low potential terminal 802 that has a lower potential than the drive voltage VD2. The low potential terminal 802 may be a reference terminal that serves as a reference potential for the drive voltage VD2. The high potential terminal 801 and the low potential terminal 802 may be terminals or cables of a power supply that supplies power to operate the first load 80A. The low potential terminal 802 may be a ground terminal, for example. The drive voltage VD2 is 36 V, for example. The drive voltage VD2 may be changed as appropriate. The reference potential is 0 V, for example. The potential of the low potential terminal 802 may be changed arbitrarily. When the first switch circuit 60A to which the first load 80A is connected is turned on, a current flows from the first connection terminal 101 toward the second connection terminal 102.

The second load 80B is, for example, a load driven in a source mode. The second load 80B is connected between the first connection terminal 101 and the low potential terminal 802. The second connection terminal 102, which is the common terminal, is connected to the high potential terminal 801 through which the drive voltage VD2 is supplied. When the second switch circuit 60B to which this second load 80B is connected is turned on, a current flows from the second connection terminal 102 toward the first connection terminal 101.

The semiconductor device 20 may include a plurality of semiconductor chips. In one example, the semiconductor device 20 may include a pulse chip 30, a transformer chip 40, and a plurality of rectifier chips 50.

The pulse chip 30 may include a plurality of pulse generation circuits 31. The pulse chip 30 may include the plurality of pulse generation circuits 31 corresponding to the plurality of switch circuits 60. In one example, the pulse chip 30 may include a first pulse generation circuit 31A, a second pulse generation circuit 31B, a third pulse generation circuit 31C, and a fourth pulse generation circuit 31D. In the following description, when the first to fourth pulse generation circuits 31A to 31D are not distinguished from one another, the first to fourth pulse generation circuits 31A to 31D are simply referred to as a pulse generation circuit 31 or each pulse generation circuit 31. The pulse generation circuit 31 generates a drive signal S2 for driving the switch circuit 60.

The pulse chip 30 may include an oscillation circuit 32. The oscillation circuit 32 outputs a clock signal CLK. In one example, the clock signal CLK is a square wave. The clock signal CLK has a predetermined frequency and a predetermined duty. The oscillation circuit 32 may be configured to be capable of changing the frequency of the clock signal CLK. The oscillation circuit 32 may also be configured to output and stop the clock signal CLK, for example, by an enable signal.

The first to fourth pulse generation circuits 31A to 31D are configured to output a pulse signal SP based on the clock signal CLK and the first to fourth control signals SIA to SID. The transformer chip 40 may include a plurality of transformers 41. In one example, the transformer chip 40 may include a first transformer 41A, a second transformer 41B, a third transformer 41C, and a fourth transformer 41D. In the following description, when the first to fourth transformers 41A to 41D are not distinguished from one another, the first to fourth transformers 41A to 41D are simply referred to as a transformer 41 or each transformer 41. Each transformer 41 includes a primary coil 42 and a secondary coil 43. The primary coils 42 of the first to fourth transformers 41A to 41D are connected to the first to fourth pulse generation circuits 31A to 31D, respectively. Each transformer 41 is configured to cause an induced current to flow through the secondary coil 43 in response to the pulse signal SP supplied from the pulse generation circuit 31 to the primary coil 42.

The semiconductor device 20 includes a plurality of rectifier chips 50. In one example, the plurality of rectifier chips 50 may include a first rectifier chip 50A, a second rectifier chip 50B, a third rectifier chip 50C, and a fourth rectifier chip 50D. In the following description, when the first to fourth rectifier chips 50A to 50D are not distinguished from one another, the first to fourth rectifier chips 50A to 50D are simply referred to as a rectifier chip 50 or each rectifier chip 50.

The first to fourth rectifier chips 50A to 50D include first to fourth rectifier circuits 51A to 51D, respectively. In the following description, when the first to fourth rectifier circuits 51A to 51D are not distinguished from one another, the first to fourth rectifier circuits 51A to 51D are simply referred to as a rectifier circuit 51 or each rectifier circuit 51. The secondary coil 43 of each transformer 41 is connected to each rectifier circuit 51. Each rectifier circuit 51 is configured to control each switch circuit 60 by rectifying the induced current flowing through the secondary coil 43 of each transformer 41.

### (Electrical Configuration of Insulation Switch)

An example of a configuration of the insulation switch 100 will be described with reference to FIG. 2. FIG. 2 shows a configuration for controlling one switch circuit 60.

The pulse chip 30 includes a plurality of output pads 34. The plurality of output pads 34 may include a first output pad 34A, a second output pad 34B, and a third output pad 34C. The pulse chip 30 includes the pulse generation circuit 31. The pulse generation circuit 31 is connected to the first output pad 34A, the second output pad 34B, and the third output pad 34C.

The transformer chip 40 includes a transformer 41. The transformer chip 40 may include a plurality of first electrode pads 44 and a plurality of second electrode pads 45. The plurality of first electrode pads 44 may include a first input pad 44A, a second input pad 44B, and a third input pad 44C. The plurality of second electrode pads 45 may include a first output pad 45A, a second output pad 45B, and a third output pad 45C.

The plurality of first electrode pads 44 of the transformer chip 40 are electrically connected to the plurality of output pads 34 of the pulse chip 30, respectively. The third input pad 44C of the transformer chip 40 is electrically connected to the third output pad 34C of the pulse chip 30. The first input pad 44A of the transformer chip 40 is electrically connected to the first output pad 34A of the pulse chip 30. The second input pad 44B of the transformer chip 40 is electrically connected to the second output pad 34B of the pulse chip 30.

The primary coil 42 of the transformer 41 includes a first coil 42A and a second coil 42B. The first coil 42A and the second coil 42B are connected to the pulse generation circuit 31. The secondary coil 43 of the transformer 41 includes a first coil 43A and a second coil 43B. The first coil 43A of the secondary coil 43 is electromagnetically coupled to the first coil 42A of the primary coil 42. The second coil 43B of the secondary coil 43 is electromagnetically coupled to the second coil 42B of the primary coil 42.

The first coil 42A of the primary coil 42 is connected between the third input pad 44C and the first input pad 44A. The second coil 42B of the primary coil 42 is connected between the third input pad 44C and the second input pad 44B.

The first coil 43A of the secondary coil 43 is connected between the third output pad 45C and the first output pad 45A. The second coil 43B of the secondary coil 43 is connected between the third output pad 45C and the second output pad 45B.

The pulse generation circuit 31 is configured to generate a first pulse signal SP1 and a second pulse signal SP2 as the pulse signal SP. The pulse generation circuit 31 supplies the first pulse signal SP1 to the first coil 42A. The pulse generation circuit 31 supplies the second pulse signal SP2 to the second coil 42B.

The pulse generation circuit 31 generates the first and second pulse signals SP1 and SP2 at a timing of rising edge of the clock signal CLK. The pulse generation circuit 31 may be configured to generate the first and second pulse signals SP1 and SP2 at a timing of falling edge of the clock signal CLK. The pulse generation circuit 31 may also be configured to generate the first and second pulse signals SP1 and SP2 at both a timing of rising edge and a timing of falling edge of the clock signal CLK.

In one example, the pulse generation circuit 31 is configured to generate the first pulse signal SP1 during a period in which the first control signal SIA is at a first level. The pulse generation circuit 31 is also configured to generate the second pulse signal SP2 during the period in which the first control signal SIA is at the first level and during a predetermined period after the first control signal SIA transitions from the first level to a second level different from the first level. The first level may be a level that allows a current to flow through the primary coil 42 of the transformer 41, and the second level may be a level that does not allow a current to flow through the primary coil 42 of the transformer 41. In one example, the first level may be a higher potential than the second level. In this case, the first level may be referred to as a Hi level, and the second level may be referred to as a Lo level.

### (Rectifier Chip)

The rectifier chip 50 may include a plurality of input pads 53 and a plurality of output pads 54. The plurality of input pads 53 may include a first input pad 53A, a second input pad 53B, and a third input pad 53C. The third input pad 53C of the rectifier chip 50 is electrically connected to the third output pad 45C of the transformer chip 40. The third input pad 53C may be called an input reference pad. The first input pad 53A of the rectifier chip 50 is electrically connected to the first output pad 45A of the transformer chip 40. The second input pad 53B of the rectifier chip 50 is electrically connected to the second output pad 45B of the transformer chip 40. The plurality of output pads 54 may include a first output pad 54A and a second output pad 54B. The first output pad 54A and the second output pad 54B are connected to the switch circuit 60.

The rectifier chip 50 includes the rectifier circuit 51. The rectifier circuit 51 may include transistors 511 to 515, transistors 521 to 527, diodes 531 to 535, capacitors 541 to 545, and resistors 551 to 557. In one example, the transistors 511 to 515 may be npn-type bipolar transistors. In one example, the transistors 521 to 526 may be n-channel metal oxide semiconductor field effect transistors (MOSFETs). In one example, the transistor 527 may be a p-channel MOSFET. In one example, the diode 531 may be a Zener diode. In one example, the diodes 532 to 535 may be pn junction diodes.

A base terminal and a collector terminal of the transistor 511 are connected to the first input pad 53A. An emitter terminal of the transistor 511 is connected to a base terminal and a collector terminal of the transistor 512 and a first terminal of the capacitor 541. A second terminal of the capacitor 541 is connected to the second input pad 53B. An emitter terminal of the transistor 512 is connected to a first terminal of the capacitor 542 and a first terminal of the resistor 551. A second terminal of the capacitor 542 is connected to the first input pad 53A. A second terminal of the resistor 551 is connected to the first output pad 54A, a cathode terminal of the diode 531, and a drain terminal of the transistor 521. An anode terminal of the diode 531 is connected to the third input pad 53C. The anode terminal of the diode 531 is also connected to the second output pad 54B. A source terminal of the transistor 521 is connected to the third input pad 53C. The source terminal of the transistor 521 is also connected to the second output pad 54B. The transistor 521 is connected between the first output pad 54A and the second output pad 54B. The third input pad 53C is connected to the second output pad 54B.

A base terminal and a collector terminal of the transistor 513 are connected to the second input pad 53B. An emitter terminal of the transistor 513 is connected to a first terminal of the resistor 552. A second terminal of the resistor 552 is connected to a drain terminal of the transistor 522, a first terminal of the resistor 557, a first terminal of the capacitor 545, and a gate terminal of the transistor 521. A back gate terminal of the transistor 521 is connected to the source terminal of the transistor 521. A back gate terminal of the transistor 522 is connected to a source terminal of the transistor 522. The source terminal of the transistor 522, a second terminal of the resistor 557, and a second terminal of the capacitor 545 are connected to the third input pad 53C and the second output pad 54B.

A collector terminal of the transistor 514 is connected to the first input pad 53A. The collector terminal of the transistor 514 is connected to a first terminal of the capacitor 543, and a second terminal of the capacitor 543 is connected to a base terminal of the transistor 514. The base terminal of the transistor 514 is connected to a first terminal of the resistor 553, and a second terminal of the resistor 553 is connected to an emitter terminal of the transistor 514. In addition, the emitter terminal of the transistor 514 is connected to a first terminal of the resistor 554, and a second terminal of the resistor 554 is connected to a gate terminal of the transistor 522 and a drain terminal of the transistor 524.

A collector terminal of the transistor 515 is connected to the second input pad 53B. The collector terminal of the transistor 515 is connected to a first terminal of the capacitor 544, and a second terminal of the capacitor 544 is connected to a base terminal of the transistor 515. The base terminal of the transistor 515 is connected to a first terminal of the resistor 555, and a second terminal of the resistor 555 is connected to an emitter terminal of the transistor 515. In addition, the emitter terminal of the transistor 515 is connected to a first terminal of the resistor 556, and a second terminal of the resistor 556 is connected to a drain terminal of the transistor 523.

A gate terminal of the transistor 523 is connected to a drain terminal of the transistor 523 and a gate terminal of the transistor 524. A back gate terminal of the transistor 523 is connected to a source terminal of the transistor 523. The source terminal of the transistor 523 is connected to the third input pad 53C and the second output pad 54B. A back gate terminal of the transistor 524 is connected to a source terminal of the transistor 524. The source terminal of the transistor 524 is connected to the third input pad 53C and the second output pad 54B.

An anode terminal of the diode 532 is connected to the third input pad 53C, and a cathode terminal of the diode 532 is connected to the first input pad 53A. An anode terminal of the diode 533 is connected to the third input pad 53C, and a cathode terminal of the diode 533 is connected to the second input pad 53B. An anode terminal of the diode 534 is connected to the first input pad 53A, and a cathode terminal of the diode 534 is connected to a drain terminal of the transistor 525. An anode terminal of the diode 535 is connected to the second input pad 53B, and a cathode terminal of the diode 535 is connected to the drain terminal of the transistor 525. A back gate terminal of the transistor 525 is connected to a source terminal of the transistor 525. A gate terminal and the source terminal of the transistor 525 are connected to the third input pad 53C. The diodes 532 to 525 and the transistor 525 constitute a protection circuit 52A for the input pad 53.

The transistor 526 is connected between the first output pad 54A and the second output pad 54B. The transistor 527 is connected between the second output pad 54B and a semiconductor substrate 571. A drain terminal of the transistor 526 is connected to the first output pad 54A, and a source terminal of the transistor 526 is connected to the second output pad 54B. A gate terminal and a back gate terminal of the transistor 526 are connected to a source terminal of the transistor 526. A source terminal of the transistor 527 is connected to the second output pad 54B, and a drain terminal of the transistor 527 is connected to the semiconductor substrate 571. A gate terminal and a back gate terminal of the transistor 527 are connected to the source terminal of the transistor 527. The transistors 526 and 527 constitute a protection circuit 52B for the output pad 54.

### (Switch Circuit)

The switch circuit 60 includes switch elements 601 and 602. The switch circuit 60 has a configuration in which the first switch element 601 and the second switch element 602 are connected in series.

In one example, the switch elements 601 and 602 may be N-channel MOSFETs. The switch elements 601 and 602 each include a source terminal, a drain terminal, a gate terminal, and a back gate terminal. The gate terminals of the switch elements 601 and 602 are connected to the first output pad 54A of the rectifier circuit 51. The back gate terminal of the switch element 601 is connected to the source terminal of the switch element 601. The back gate terminal of the switch element 602 is connected to the source terminal of the switch element 602. The source terminals of the switch elements 601 and 602 are connected to the second output pad 54B of the rectifier circuit 51. The drain terminal of the switch element 601 is connected to the first connection terminal 101, and the drain terminal of the switch element 602 is connected to the second connection terminal 102. Therefore, the switch elements 601 and 602 are connected in series between the first connection terminal 101 and the second connection terminal 102.

FIG. 2 shows the load 80A connected to the first connection terminal 101 of the insulation switch 100. The drive voltage VD2 is supplied to the load 80A. The second connection terminal 102 of the insulation switch 100 is connected to the low potential terminal 802.

### (Operation of Insulation Switch)

An operation of the insulation switch 100 will be described with reference to FIG. 2 and FIG. 3. The pulse generation circuit 31 generates the first pulse signal SP1 during a period in which the control signal S1 is at a Hi level. The first pulse signal SP1 is supplied to the first coil 42A of the primary coil 42 of the transformer 41. As a result, a first induced current I21 is generated in the first coil 43A of the secondary coil 43 of the transformer 41 and flows from the third output pad 45C toward the first output pad 45A. The first induced current I21 generated in the first coil 43A of the transformer 41 flows from the first input pad 53A of the rectifier chip 50 toward the transistor 511.

The transistors 511 and 512 are diode-connected. Further, the transistors 511 and 512 are connected so as to be in a forward direction with respect to the first induced current I21 flowing in the first coil 43A of the secondary coil 43 of the transformer 41. The first induced current I21 is rectified by the transistors 511 and 512. Voltages at the emitter terminals of the transistors 511 and 512 are smoothed by the capacitors 541 and 542.

The pulse generation circuit 31 also generates the second pulse signal SP2 in response to the control signal S1. The second pulse signal SP2 is supplied to the second coil 42B of the primary coil 42 of the transformer 41. As a result, a second induced current I22 is generated in the second coil 43B of the secondary coil 43 in the transformer 41 and flows from the third output pad 45C toward the second output pad 45B.

The second terminal of the capacitor 542 is connected to the first input pad 53A. The first induced current I21 is supplied to the second terminal of the capacitor 542. A voltage level at the second terminal of the capacitor 542 changes according to the first induced current I21. On the other hand, the second terminal of the capacitor 541 is connected to the second input pad 53B. The second induced current I22 is supplied to the second terminal of the capacitor 541. A voltage level at the second terminal of the capacitor 541 changes according to the second induced current I22. Therefore, the voltage level at the second terminal of the capacitor 541 and the voltage level at the second terminal of the capacitor 542 alternately rise and fall in a complementary manner. By such an operation, the transistors 511 and 512 and the capacitors 541 and 542 constitute a two-stage boost circuit. The number of stages of the boost circuit may be changed as appropriate. In one example, the rectifier circuit 51 may be configured to include the transistor 511 and the capacitor 541 that constitute a single-stage boost circuit. The rectifier circuit 51 may also include a boost circuit with three or more stages.

The rectifier circuit 51 makes a voltage at the first terminal of the capacitor 541, that is, a voltage at the first output pad 54A, higher than voltages at the third input pad 53C and the second output pad 54B. Further, the rectifier circuit 51 maintains the voltage at the first output pad 54A at a constant voltage. In one example, a value of the constant voltage may be determined by a reverse voltage of the diode 531. A potential difference between the second output pad 54B and the first output pad 54A becomes a voltage level of the drive signal S2. This drive signal S2 is supplied to the switch circuit 60. Specifically, the drive signal S2 is supplied as a source-gate voltage of the first switch element 601 and the second switch element 602 included in the switch circuit 60. The transistors 511 and 512, the capacitors 541 and 542, the resistor 551, and the diode 531 constitute a first signal generation circuit 52C that rectifies the first induced current I21 flowing through the secondary coil 43 (the first coil 43A) of the transformer 41 to generate the drive signal S2.

The first induced current I21 is also supplied to the collector terminal of the transistor 514. The capacitor 543 is connected between the collector terminal and the base terminal of the transistor 514. The resistor 553 is connected between the base terminal and the emitter terminal of the transistor 514. The capacitor 543 and the resistor 553 increase a voltage of the emitter terminal of the transistor 514 as compared to a case where the collector terminal and the base terminal of the transistor 514 are directly connected. The emitter terminal of the transistor 514 is connected to the gate terminal of the transistor 522 via the resistor 554.

The transistor 522 is connected between the gate terminal of the transistor 521 and the source terminal of the transistor 521. The transistor 522 is turned on by the voltage of the emitter terminal of the transistor 514. Therefore, since a voltage of the gate terminal of the transistor 521 becomes equal to a voltage of the source terminal of the transistor 521, the transistor 521 is turned off. The first induced current I21 is supplied to the gate terminal of the transistor 522 via the transistor 514 and the resistor 554. Therefore, while the first induced current I21 is being generated, since the transistor 522 is turned on and an off state of the transistor 521 is maintained, a voltage level Vo of the drive signal S2 is maintained.

That is, the transistor 514, the capacitor 543, the resistors 553 and 554, and the transistor 522 turn on the transistor 522 by the first induced current I21. By turning on the transistor 522, the transistor 521 between the first output pad 54A and the second output pad 54B is turned off. Therefore, it can be said that the transistor 514, the capacitor 543, the resistors 553 and 554, and the transistor 522 constitute a holding circuit that maintains the voltage level of the drive signal S2.

The second induced current I22 is supplied to the collector terminal of the transistor 513. The gate terminal of the transistor 513 is connected to the collector terminal of the transistor 513. Therefore, the transistor 513 acts as a diode connected in a forward direction with respect to the second induced current I22. The second induced current I22 is supplied to the first terminal of the capacitor 545 via the transistor 513. The first terminal of the capacitor 545 is connected to the gate terminal of the transistor 521. A voltage at the first terminal of the capacitor 545 becomes the gate-source voltage of the transistor 521 due to the supplied second induced current I22. When the gate-source voltage of the transistor 521 becomes higher than a threshold voltage Vth of the transistor 521, the transistor 521 is turned on. Here, while the first induced current I21 is being generated, the transistor 522 is turned on by the transistor 514, the capacitor 543, and the resistors 553 and 554, thereby maintaining the transistor 521 in the off state.

In addition, while the first induced current I21 is not being generated and the second induced current I22 is being generated, that is, during a predetermined period after the control signal S1 transitions from the first level to the second level, the transistor 521 is turned on by the gate voltage due to the second induced current I22. By turning on the transistor 521, the voltage level of the drive signal S2 drops to a voltage level of the second output pad 54B. When the voltage level of the drive signal S2 becomes lower than a threshold voltage of the first switch element 601, the first switch element 601 is turned off, that is, the switch circuit 60 is turned off.

The second induced current I22 is also supplied to the collector terminal of the transistor 515. The capacitor 544 is connected between the collector terminal and the base terminal of the transistor 515. The resistor 555 is connected between the base terminal and the emitter terminal of the transistor 515.

The emitter terminal of the transistor 515 is connected to the drain terminal of the transistor 523. The gate terminal of the transistor 523 is connected to the drain terminal of the transistor 523 and the gate terminal of the transistor 524. The drain terminal of the transistor 524 is connected to the gate terminal of the transistor 522. The source terminal of the transistor 523 and the source terminal of the transistor 524 are connected to each other and to the second output pad 54B (the third input pad 53C). The transistors 523 and 524 form a current mirror circuit. This current mirror circuit operates to cause a current proportional to a current flowing through the transistor 523 to flow from the gate terminal of the transistor 522. Therefore, when the first induced current I21 is no longer generated, since a voltage of the gate terminal of the transistor 522 drops quickly, the transistor 522 is turned off. By turning off the transistor 522, the transistor 521 is turned on, and the voltage level of the drive signal S2 drops. The transistors 523 and 524 form a circuit that turns off the transistor 522 to keep the transistor 521 off by the second induced current I22 after the first induced current I21 stops.

The drive signal S2 is supplied to the gate terminals of the first switch element 601 and the second switch element 602 of the switch circuit 60. The source terminals of the first switch element 601 and the second switch element 602 are connected to the second output pad 54B. Therefore, when the drive signal S2 becomes higher than the threshold voltage of the first switch element 601, the first switch element 601 is turned on. At this time, the second switch element 602 functions as a diode with a forward direction being a direction from the first switch element 601 toward the second connection terminal 102. As a result, the switch circuit 60 becomes conductive. This conductive switch circuit 60 allows a current to flow from the load 80 to the low potential terminal 802 via the switch circuit 60, thereby driving the load 80.

### (Configuration of Semiconductor Device)

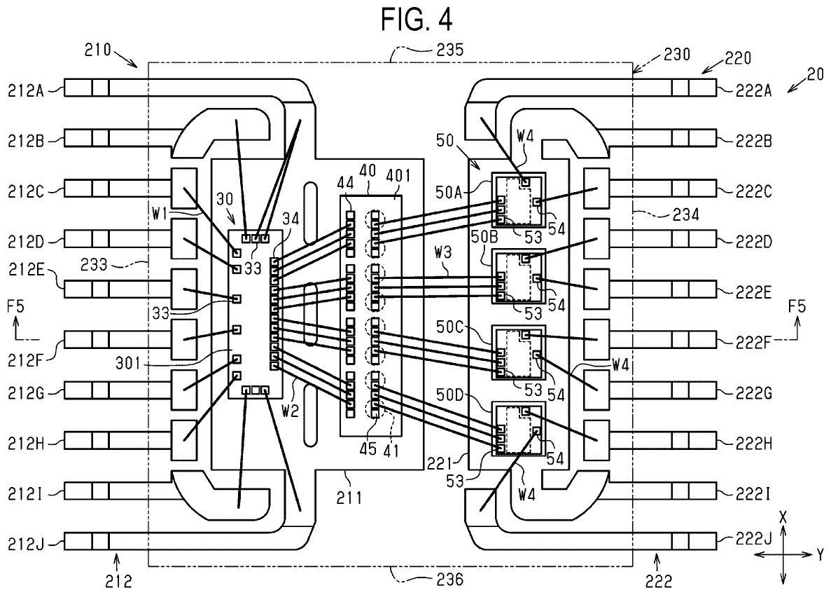

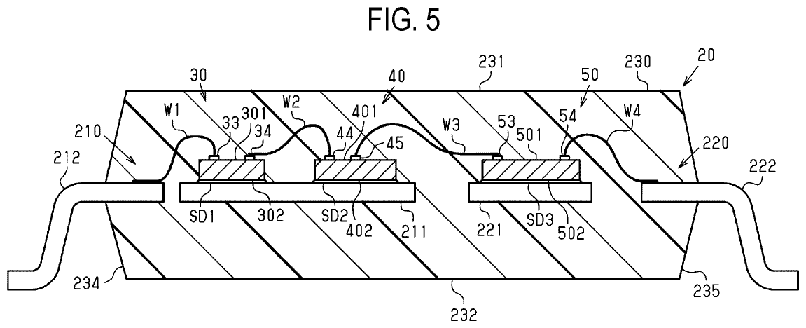

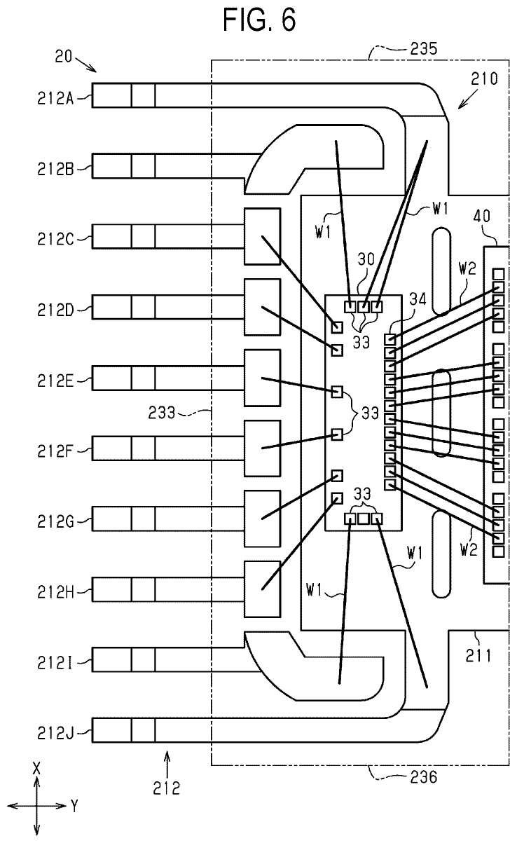

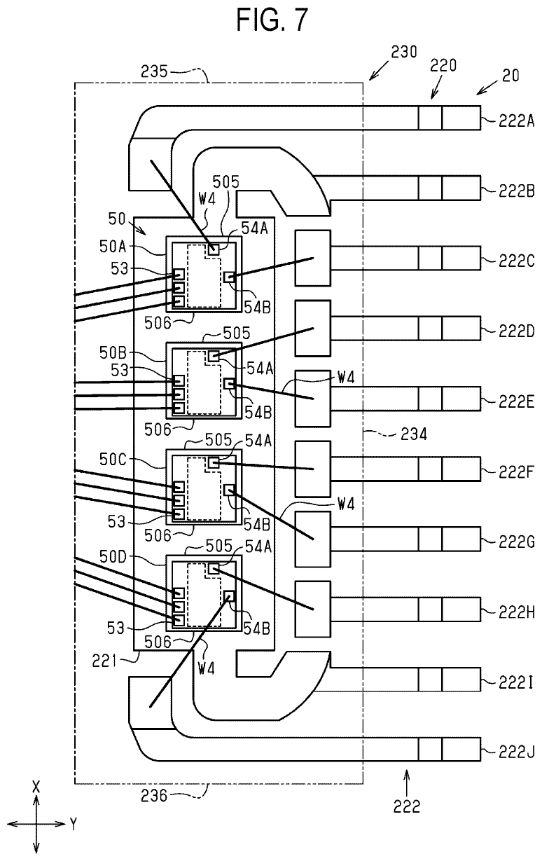

An example of a configuration of the semiconductor device 20 will be described with reference to FIG. 4 to FIG. 7. FIG. 4 is a schematic plan view showing an example of the semiconductor device 20. FIG. 5 is a schematic side view of the semiconductor device 20 of FIG. 4. FIG. 6 is a schematic plan view of a portion of the semiconductor device 20 of FIG. 4, and shows an enlarged view of a first lead terminal 212 and the pulse chip 30. FIG. 7 is a schematic plan view of a portion of the semiconductor device 20 of FIG. 4 and shows an enlarged view of the rectifier chip 50 and a second lead terminal 222.

As shown in FIG. 4 and FIG. 5, the semiconductor device 20 is a semiconductor device in which a plurality of semiconductor chips is packaged together. The semiconductor device 20 includes the pulse chip 30, the transformer chip 40, and the plurality of rectifier chips 50, as a semiconductor chip.

A package format of the semiconductor device 20 is a small outline (SO) type, for example, a small outline package (SOP). The package format of the semiconductor device 20 can be changed as desired. The package format is not limited to an SOP but may be a quad for non-lead package (QFN), a dual flat package (DFP), a dual inline package (DIP), a quad flat package (QFP), a single inline package (SIP), or a small outline J-leaded package (SOJ), or various package structures similar thereto.

The semiconductor device 20 includes a first support 210, a second support 220, and a scaling resin 230. The pulse chip 30 is mounted on the first support 210. In one example, the transformer chip 40 is mounted on the first support 210. The plurality of rectifier chips 50 are mounted on the second support 220. The sealing resin 230 seals portions of the first support 210 and the second support 220, the pulse chip 30, the transformer chip 40, and the rectifier chip 50. In FIG. 4 and FIG. 5, the scaling resin 230 is indicated by a two-dot chain line for the convenience of explaining an internal structure of the semiconductor device 20.

The sealing resin 230 is made of a resin material having electrical insulation properties. The resin material may be, for example, a resin containing epoxy resin. The resin material may also be colored in black or the like. The sealing resin 230 is formed in a rectangular plate shape with its thickness direction being a Z direction. The sealing resin 230 includes a sealing upper surface 231 and a sealing lower surface 232 on an opposite side of the sealing upper surface 231. The scaling upper surface 231 and the sealing lower surface 232 are separated from each other in the Z direction. The sealing resin 230 also includes four resin side surfaces 233 to 236 that connect the sealing upper surface 231 and the sealing lower surface 232. The sealing resin 230 includes the resin side surfaces 233 and 234 as both end surfaces in an X direction, and the resin side surfaces 235 and 236 as both end surfaces in a Y direction. The X direction and the Y direction are perpendie ular to the Z direction. The X direction and the Y direction are perpendie ular to each other. The X direction corresponds to a “second direction.” The Y direction corresponds to a “first direction.” In the following description, a plan view means a view from the Z direction.

The first support 210 and the second support 220 each have conductivity. The first support 210 and the second support 220 are made of a material containing Cu (copper), Fe (iron), or the like. The first support 210 and the second support 220 are provided across an inside and an outside of the scaling resin 230.

The first support 210 includes a first die pad 211 disposed in the sealing resin 230, and a plurality of first lead terminals 212 disposed across the inside and the outside of the scaling resin 230. The first die pad 211 corresponds to a “second frame.” The first lead terminals 212 correspond to “second leads.”

The first die pad 211 has both the pulse chip 30 and the transformer chip 40 mounted thereon. In a plan view, the first die pad 211 is disposed so that its center in the Y direction is closer to the resin side surface 235 than a center of the sealing resin 230 in the Y direction. The first die pad 211 is not exposed from the sealing resin 230. In a plan view, a shape of the first die pad 211 is rectangular with its long side in the X direction and its short side in the Y direction.

The plurality of first lead terminals 212 are arranged to be spaced apart from one another in the X direction. A portion of each first lead terminal 212 protrudes from the resin side surface 235 toward the outside of the scaling resin 230.

As shown in FIG. 4 and FIG. 5, the second support 220 includes a second die pad 221 disposed in the sealing resin 230, and a plurality of second lead terminals 222 arranged across the inside and the outside of the sealing resin 230. The second die pad 221 corresponds to a “first frame.” The second lead terminals 222 correspond to “first leads.”

The plurality of rectifier chips 50 are mounted on the second die pad 221. In a plan view, the second die pad 221 is disposed to be closer to the resin side surface 236 than the first die pad 211 in the Y direction. The second die pad 221 is not exposed from the sealing resin 230. In a plan view, a shape of the second die pad 221 is rectangular with its long side in the X direction and its short side in the Y direction.

The first die pad 211 and the second die pad 221 are arranged to be spaced apart from each other in the Y direction. Therefore, the Y direction can also be said to be an arrangement direction of both die pads 211 and 221. Dimensions of the first die pad 211 and the second die pad 221 in the Y direction are set according to a size and the number of semiconductor chips to be mounted. The pulse chip 30 and the transformer chip 40 are mounted on the first die pad 211, and the plurality of rectifier chips 50 are mounted on the second die pad 221. Therefore, the dimension of the first die pad 211 in the Y direction is larger than the dimension of the second die pad 221 in the Y direction.

The plurality of second lead terminals 222 are arranged to be spaced apart from one another in the X direction. A portion of each second lead terminal 222 protrudes from the resin side surface 236 toward the outside of the sealing resin 230.

The number of second lead terminals 222 is the same as the number of first lead terminals 212. As can be seen from FIG. 4, the plurality of first lead terminals 212 and the plurality of second lead terminals 222 are arranged in a direction (the X direction) perpendicular to the arrangement direction (the Y direction) of the first die pad 211 and the second die pad 221. Further, the number of second lead terminals 222 and the number of first lead terminals 212 can be changed arbitrarily.

The pulse chip 30, the plurality of rectifier chips 50, and the transformer chip 40 are arranged to be spaced apart from one another in the Y direction. The pulse chip 30, the transformer chip 40, and the plurality of rectifier chips 50 are arranged in this order from the first lead terminal 212 toward the second lead terminal 222 in the Y direction.

The plurality of rectifier chips 50 are arranged to be spaced apart from one another in the X direction in a plan view. It can be said that the plurality of rectifier chips 50 are arranged in the X direction, which intersects the Y direction in which the pulse chip 30 and the transformer chip 40 are arranged.

The pulse chip 30 includes the oscillation circuit 32 and the plurality of pulse generation circuits 31 shown in FIG. 1. In a plan view, the pulse chip 30 has a rectangular shape with its short and long sides. In a plan view, the pulse chip 30 is mounted on the first die pad 211 so that the long side is aligned along the X direction and the short side is aligned along the Y direction.

As shown in FIG. 5, the pulse chip 30 includes a chip top surface 301 and a chip bottom surface 302 on an opposite side of the chip top surface 301. The chip bottom surface 302 of the pulse chip 30 is bonded to the first die pad 211 by a bonding material SD1. The bonding material SD1 may have conductivity. The conductive bonding material SD1 may be solder, Ag (silver) paste, or the like. The bonding material SD1 may have insulation property. As shown in FIG. 4, a plurality of input pads 33 and a plurality of output pads 34 are disposed on the chip top surface 301 of the pulse chip 30.

Each of the plurality of rectifier chips 50 includes the rectifier circuit 51 shown in FIG. 1. A shape of each of the plurality of rectifier chips 50 in a plan view may be approximately square. Each of the plurality of rectifier chips 50 may have a rectangular shape with a plurality of short sides and long sides. In a plan view, the plurality of rectifier chips 50 are arranged along the X direction.

As shown in FIG. 5, each of the plurality of rectifier chips 50 includes a chip top surface 501 and a chip bottom surface 502 on an opposite side of the chip top surface 501. The chip bottom surface 502 of each of the plurality of rectifier chips 50 is bonded to the second die pad 221 by a bonding material SD3. The bonding material SD3 may have insulation property. The bonding material SD3 may have conductivity.

A plurality of input pads 53 and a plurality of output pads 54 are disposed on the chip top surfaces 501 of the plurality of rectifier chips 50. The plurality of input pads 53 are disposed at an end portion closer to the transformer chip 40, among both end portions of the chip top surface 501 in the Y direction, than the plurality of output pads 54. The plurality of input pads 53 are arranged in the X direction. The plurality of output pads 54 are disposed at an end portion farther from the transformer chip 40, among both end portions of the chip top surface 501 in the Y direction. In other words, the plurality of output pads 54 are disposed to be closer to the second lead terminal 222 than the plurality of input pads 53.

The transformer chip 40 includes the plurality of transformers 41 shown in FIG. 1. A shape of the transformer chip 40 in a plan view is rectangular with its short and long sides. In a plan view, the transformer chip 40 is mounted on the first die pad 211 so that the long side is aligned with the X direction and the short side is aligned with the Y direction.

The transformer chip 40 is disposed to be adjacent to the pulse chip 30 in the Y direction. The transformer chip 40 is disposed to be closer to the rectifier chips 50 than the pulse chip 30. In other words, the transformer chip 40 is disposed between the pulse chip 30 and the rectifier chips 50 in the Y direction.

As shown in FIG. 5, the transformer chip 40 includes a chip top surface 401 and a chip bottom surface 402 on an opposite side of the chip top surface 401. The chip bottom surface 402 of the transformer chip 40 is bonded to the first die pad 211 by a bonding material SD2. The bonding material SD2 may have conductivity. The conductive bonding material SD2 may be solder, Ag paste, or the like. The bonding material SD2 may have insulation property.

As shown in FIG. 4, the transformer chip 40 includes a plurality of first electrode pads 44 and a plurality of second electrode pads 45. The plurality of first electrode pads 44 and the plurality of second electrode pads 45 are provided on the chip top surface 401 of the transformer chip 40.

A plurality of wires W1 to W4 are connected to the pulse chip 30, the transformer chip 40, and each of the rectifier chips 50. Each of the wires W1 to W4 is a bonding wire formed by a wire bonding device, and is formed of a conductor containing, for example, Au (gold), Al (aluminum), Cu, and the like.

The pulse chip 30 is electrically connected to the first lead terminals 212 by the wires W1. More specifically, the plurality of input pads 33 of the pulse chip 30 and the plurality of first lead terminals 212 are connected by the wires W1.

The plurality of rectifier chips 50 and the plurality of second lead terminals 222 of the second support 220 are electrically connected to each other by the wires W4. More specifically, the plurality of output pads 54 of the plurality of rectifier chips 50 and the second lead terminals 222 are connected by the wires W4.

The transformer chip 40 is connected to the pulse chip 30 by the wires W2. The transformer chip 40 is also connected to the rectifier chips 50 by the wires W3. More specifically, the plurality of first electrode pads 44 of the transformer chip 40 are connected to the plurality of output pads 34 of the pulse chip 30 by the wires W2. The plurality of second electrode pads 45 of the transformer chip 40 are connected to the plurality of input pads 53 of the rectifier chips 50 by the wires W3.

### (Details of First Lead Terminal)

As shown in FIG. 6, the plurality of first lead terminals 212 include first lead terminals 212A to 212J arranged in the X direction.

The first lead terminals 212A and 212J disposed at both ends in the X direction are connected to the first die pad 211. The first lead terminals 212A and 212J are integrated with the first die pad 211. These first lead terminals 212A and 212J may be called suspension leads.

The first lead terminals 212A and 212J connected to the first die pad 211 may be, for example, external terminals for applying a predetermined first potential to a circuit included in the pulse chip 30. Potentials of the first lead terminals 212A and 212J may be, for example, 0 V, and may be called a first ground GND1. The pulse chip 30 includes input pads 33 connected to the first lead terminals 212A and 212J by the wires W1. These input pads 33 of the pulse chip 30 may be called ground pads.

The first lead terminals 212D to 212G may be, for example, input terminals for supplying the control signals SIA to SID shown in FIG. 1 to the pulse chip 30. In one example, the first lead terminals 212C and 212H may be input terminals for supplying a predetermined control signal to the pulse chip 30. The predetermined control signal may include an enable signal, and the like.

The first lead terminals 212B and 212I may be power supply terminals for supplying the operating voltage VD1 to the circuit included in the pulse chip 30. The pulse chip 30 includes input pads 33 connected to the first lead terminals 212B and 212I by the wires W1. These input pads 33 may be called power supply pads of the pulse chip 30.

In addition, the connection and the allocation of the first lead terminals 212A to 212J shown in FIG. 6 is an example and may be changed as appropriate. For example, at least one of the first lead terminal 212A or 212J may be separated from the first die pad 211.

(Details of Connection between Rectifier Chip and Second Lead Terminal)

As shown in FIG. 7, the plurality of second lead terminals 222 include second lead terminals 222A to 222J arranged in the X direction.

The second lead terminals 222B and 222I are connected to the second die pad 221. The second lead terminals 222B and 222I are integrated with the second die pad 221. These second lead terminals 222B and 222I may be called suspension leads.

The second lead terminals 222 not connected to the second die pad 221 may be connection terminals connected to the switch circuit 60 shown in FIG. 2. The first output pad 54A of the first rectifier chip 50A is electrically connected to the second lead terminal 222A by the wire W4. The second output pad 54B of the first rectifier chip 50A is electrically connected to the second lead terminal 222C by the wire W4. The first output pad 54A of the second rectifier chip 50B is electrically connected to the second lead terminal 222D by the wire W4. The second output pad 54B of the second rectifier chip 50B is electrically connected to the second lead terminal 222E by the wire W4. The first output pad 54A of the third rectifier chip 50C is electrically connected to the second lead terminal 222F by the wire W4. The second output pad 54B of the third rectifier chip 50C is electrically connected to the second lead terminal 222G by the wire W4. The first output pad 54A of the fourth rectifier chip 50D is electrically connected to the second lead terminal 222H by the wire W4. The second output pad 54B of the fourth rectifier chip 50D is electrically connected to the second lead terminal 222J by the wire W4.

In addition, the connection and the allocation of the second lead terminals 222A to 222J shown in FIG. 7 are merely examples and may be changed as appropriate. For example, at least one of the second lead terminal 222B or 222I may be separated from the second die pad 221.

### (Transformer Chip)

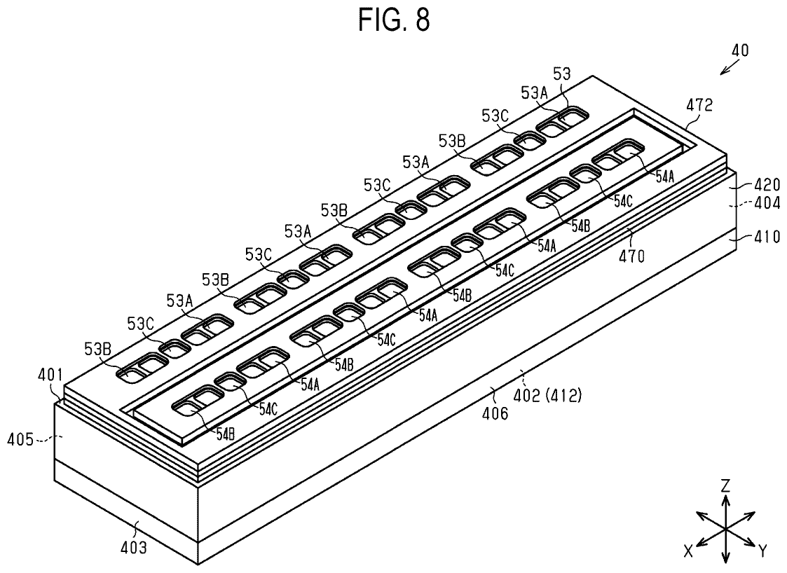

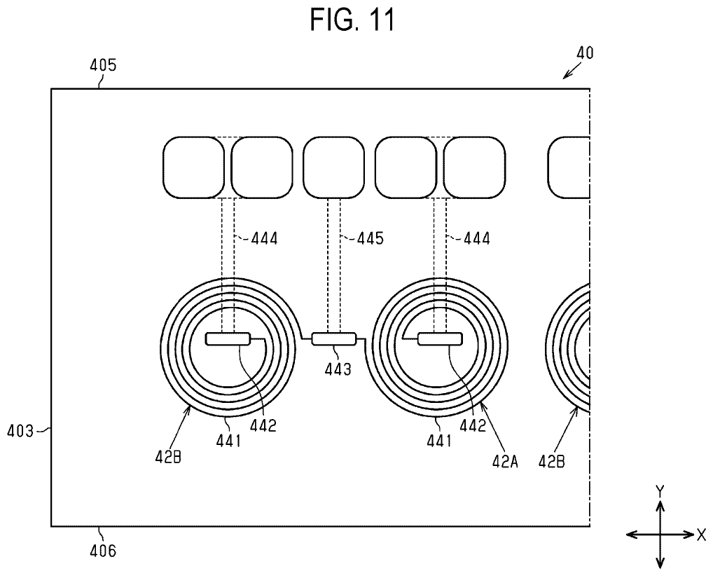

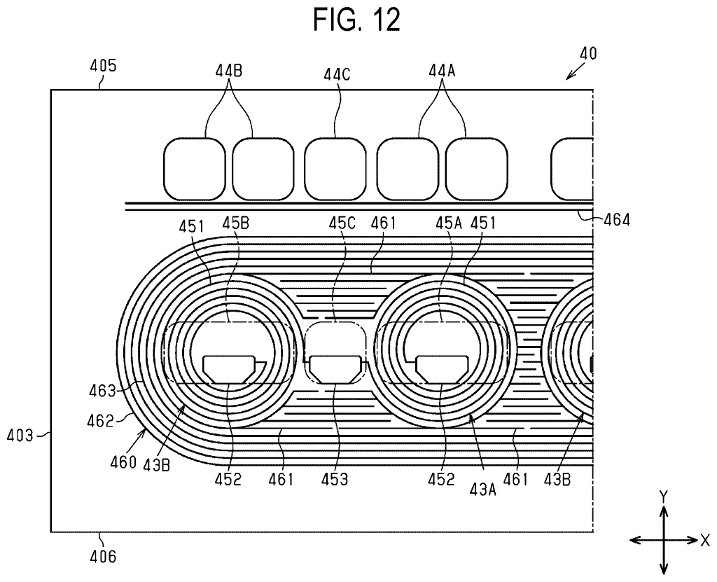

An example of the transformer chip 40 will be described with reference to FIG. 8 to FIG. 14. In the following description, a direction from the chip bottom surface 402 to the chip top surface 401 of the transformer chip 40 shown in FIG. 11 and FIG. 12 is referred to as “upward,” and a direction from the chip top surface 401 to the chip bottom surface 402 is referred to as “downward.”

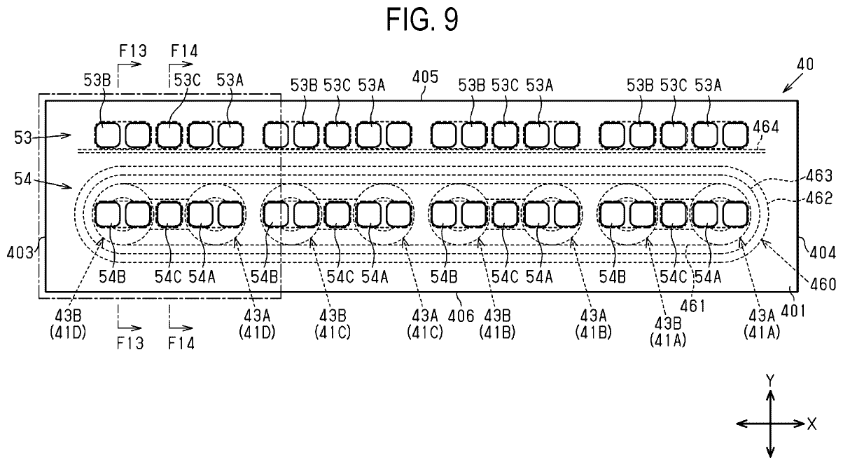

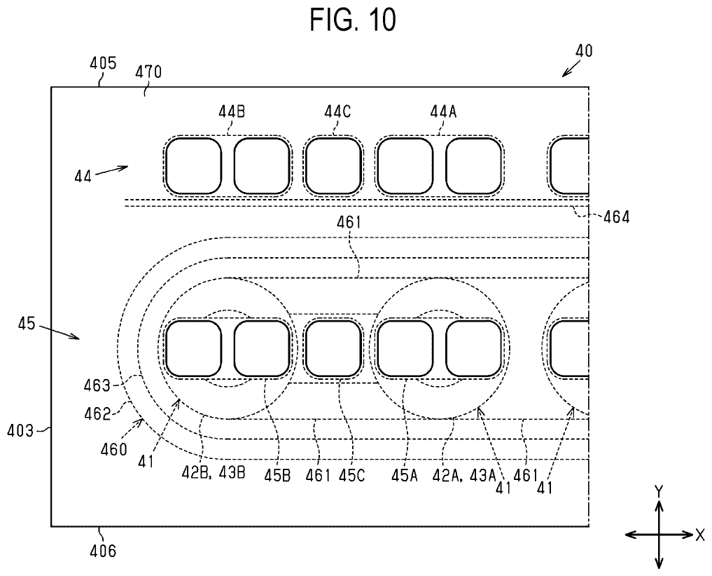

FIG. 8 is a schematic perspective view showing the transformer chip 40 of FIG. 4. FIG. 9 is a schematic plan view of the transformer chip 40 of FIG. 8. In FIG. 9, the transformer 41 and a dummy wiring 460 are shown by broken lines. FIG. 10 is a schematic plan view showing an enlarged portion of the transformer chip 40 of FIG. 9. FIG. 11 is a schematic plan view showing the primary coil 42 of the transformer chip 40 of FIG. 9. FIG. 11 is a cross-sectional view of the transformer chip 40 cut in an XY plane at a position of the primary coil 42 in the Z direction and shows a connection relationship of the primary coil 42.

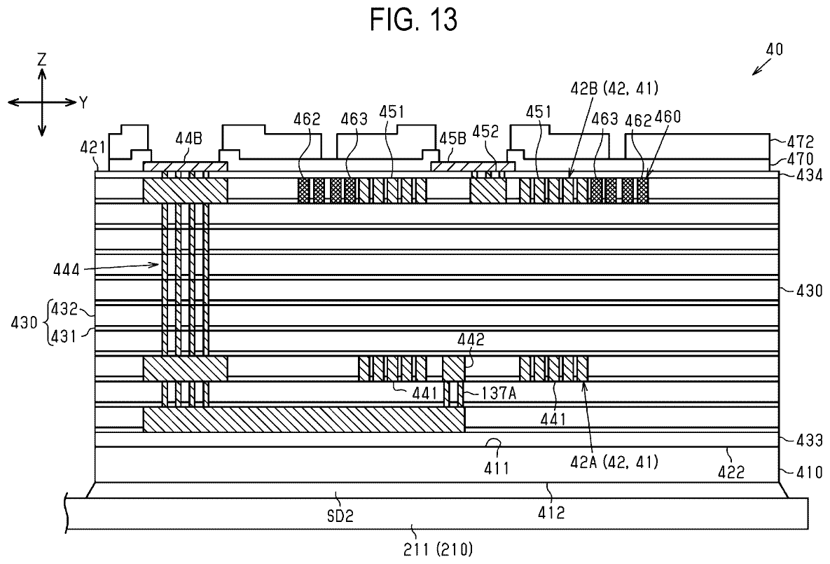

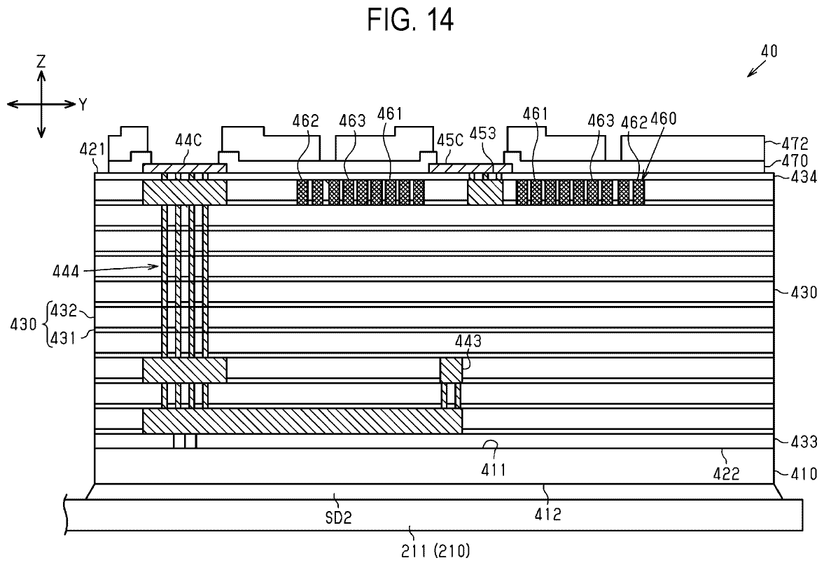

FIG. 12 is a schematic plan view showing the secondary coil 43 of the transformer chip 40 of FIG. 9. FIG. 12 is a cross-sectional view of the transformer chip 40 cut in an XY plane at a position of the secondary coil 43 in the Z direction and shows a connection relationship of the secondary coil 43. For the sake of convenience, hatching is omitted in FIG. 11 and FIG. 12. FIG. 13 is a schematic cross-sectional view of the transformer chip 40 cut along line F13-F13 in FIG. 9. FIG. 13 shows cross-sectional structures of the primary coil 42, the secondary coil 43, the dummy wiring 460, the first input pad 44A, and the first output pad 45A. FIG. 14 is a schematic cross-sectional view of the transformer chip 40 cut along line F14-F14 in FIG. 9. FIG. 14 shows cross-sectional structures of the dummy wiring 460, the third input pad 44C, and the third output pad 45C. For the sake of convenience, hatching is omitted for some components in FIG. 13 and FIG. 14.

As shown in FIG. 8 and FIG. 9, the transformer chip 40 includes the chip top surface 401 and the chip bottom surface 402 on the opposite side of the chip top surface 401. The transformer chip 40 also includes a plurality of chip side surfaces 403 to 406 that connect the chip top surface 401 and the chip bottom surface 402. The chip bottom surface 402 is formed of a semiconductor substrate 410. The plurality of electrode pads 44 and 45 are exposed from the chip top surface 401. The first chip side surface 403 and the second chip side surface 404 form both end surfaces of the transformer chip 40 in the X direction. The third chip side surface 405 and the fourth chip side surface 406 form both end surfaces of the transformer chip 40 in the Y direction.

As shown in FIG. 9, the transformer chip 40 includes the first to fourth transformers 41A to 41D. More specifically, the transformer chip 40 is a semiconductor chip in which the first to fourth transformers 41A to 41D are integrated into a single chip. In the first to fourth transformers 41A to 41D, the first coils 42A and 43A and the second coils 42B and 43B are disposed alternately. In detail, in each of the transformers 41A to 41D, the first coils 42A and 43A are disposed to be closer to the chip side surface 403 than the second coils 42B and 43B, and the second coils 42B and 43B are disposed to be closer to the chip side surface 404 than the first coils 42A and 43A.

The first to fourth transformers 41A to 41D are disposed near a center of the chip top surface 401 in the Y direction in a plan view. The first electrode pad 44 and the second electrode pad 45 are electrically connected to the first to fourth transformers 41A to 41D. The plurality of electrode pads 44 and 45 are made of a material containing one or more appropriately selected from titanium (Ti), titanium nitride (TiN), Au, Ag, Cu, Al, and tungsten (W). The plurality of electrode pads 44 and 45 are made of a material containing, for example, Al.

The plurality of first electrode pads 44 are disposed to be closer to the third chip side surface 405 than the first to fourth transformers 41A to 41D in a plan view. In other words, the plurality of first electrode pads 44 are disposed between the first to fourth transformers 41A to 41D and the third chip side surface 405 in the Y direction in a plan view.

Each of the electrode pads 44 and 45 has a shape that is long in the X direction in which the plurality of electrode pads 44 and 45 are arranged in a plan view. In one example, the shape of each of the electrode pads 44 and 45 is rectangular with its long side in the X direction and its short side in the Y direction.

As shown in FIG. 9 to FIG. 12, the plurality of first electrode pads 44 are connected to the primary coil 42 of the transformer 41. The primary coil 42 includes the first coil 42A and the second coil 42B. The plurality of first electrode pads 44 include the first input pad 44A connected to the first coil 42A, the second input pad 44B connected to the second coil 42B, and the third input pad 44C connected to both the first coil 42A and the second coil 42B. The third input pad 44C is provided as a common pad for the first coil 42A and the second coil 42B.

The plurality of second electrode pads 45 are connected to the secondary coil 43 of the transformer 41. The secondary coil 43 includes the first coil 43A and the second coil 43B. The plurality of second electrode pads 45 include the first output pad 45A connected to the first coil 43A, the second output pad 45B connected to the second coil 43B, and the third output pad 45C connected to both the first coil 43A and the second coil 43B. The third output pad 45C is provided as a common pad for the first coil 43A and the second coil 43B.

As shown in FIGS. 8, FIG. 13, and FIG. 14, the transformer chip 40 includes the semiconductor substrate 410 and an insulating layer 420 formed on the semiconductor substrate 410. The semiconductor substrate 410 may be, for example, a substrate formed from a material including Si (silicon).

The semiconductor substrate 410 includes a substrate top surface 411 and a substrate bottom surface 412 on an opposite side of the substrate top surface 411. The substrate bottom surface 412 constitutes the chip bottom surface 402 of the transformer chip 40.

As shown in FIG. 13 and FIG. 14, the insulating layer 420 includes a top surface 421 and a bottom surface 422 facing an opposite side of the top surface 421. The insulating layer 420 includes a plurality of insulating films 430 stacked in the Z direction from the substrate top surface 411 of the semiconductor substrate 410. In other words, the Z direction can also be said to be a thickness direction of the insulating layer 420. The Z direction can also be said to be a stacking direction of the insulating films 430. The insulating layer 420 is formed on the substrate top surface 411 of the semiconductor substrate 410.

The insulating films 430 include a first insulating film 431 and a second insulating film 432 formed on the first insulating film 431. The first insulating film 431 may be made of a material including SiN (silicon nitride), SiC, SiCN (nitrogen-added silicon carbide), and the like. The second insulating film 432 is, for example, an interlayer insulating film. The second insulating film 432 may be made of a material containing SiO₂ (silicon oxide). A thickness of the second insulating film 432 may be thicker than a thickness of the first insulating film 431. Both a lowermost insulating film 433 in contact with the substrate top surface 411 of the semiconductor substrate 410 and an uppermost insulating film 434 may be formed by the second insulating film 432.

### (Primary Coil)

As shown in FIG. 11, the first coil 42A and the second coil 42B of the primary coil 42 arc formed of a first coil wiring 441. A shape of the first coil wiring 441 is annular in a plan view, and in one example, may be a circular spiral shape. The first coil wiring 441 may be made of a material containing one or more appropriately selected from Ti (titanium), TiN (titanium nitride), Au, Ag, Cu, Al, and W. In one example, the first coil wiring 441 is made of a material containing Cu.

An inner end wiring 442 is disposed inside the first coil wiring 441, and an outer end wiring 443 is disposed outside the first coil wiring 441. One end of the first coil wiring 441 is electrically connected to the inner end wiring 442, and the other end of the first coil wiring 441 is electrically connected to the outer end wiring 443.

The inner end wiring 442 and the outer end wiring 443 are made of a material containing one or more appropriately selected from Ti, TiN, Au, Ag, Cu, Al, and W. In one example, the inner end wiring 442 and the outer end wiring 443 are made of a material containing Cu. The outer end wiring 443 is configured as a common end wiring for the first coil 42A and the second coil 42B. The outer end wiring 443 may be provided for each of the first coil 42A and the second coil 42B.

As shown in FIG. 11 and FIG. 13, the inner end wiring 442 is connected to the first input pad 44A by a connection wiring 444. The connection wiring 444 is made of a material containing one or more appropriately selected from Ti, TiN, Au, Ag, Cu, Al, and W. As shown in FIG. 13, the connection wiring 444 may include a first wiring portion that extends in the Z direction so as to penetrate the plurality of insulating films 430, and a second wiring portion that extends in the Y direction.

As shown in FIG. 11 and FIG. 14, the outer end wiring 443 is electrically connected to the third input pad 44C by a connection wiring 445. The connection wiring 445 is made of a material containing one or more appropriately selected from Ti, TiN, Au, Ag, Cu, Al, and W. As shown in FIG. 14, the connection wiring 445 may include a first wiring portion that extends in the Z direction so as to penetrate the plurality of insulating films 430, and a second wiring portion that extends in the Y direction.

### (Secondary Coil)

As shown in FIG. 12, the first coil 43A and the second coil 43B of the secondary coil 43 include a second coil wiring 451. A shape of the second coil wiring 451 is annular in a plan view, and in one example, may be a circular spiral shape. The second coil wiring 451 is made of a material containing one or more appropriately selected from Ti, TiN, Au, Ag, Cu, Al, and W. In one example, the second coil wiring 451 is made of a material containing Cu.

An inner end wiring 452 is disposed in a region surrounded by the second coil wiring 451, and an outer end wiring 453 is disposed outside the second coil wiring 451. One end of the second coil wiring 451 is electrically connected to the inner end wiring 452, and the other end of the second coil wiring 451 is electrically connected to the outer end wiring 453.

The inner end wiring 452 and the outer end wiring 453 are made of a material containing one or more appropriately selected from Ti, TiN, Au, Ag, Cu, Al, and W. In one example, the inner end wiring 452 and the outer end wiring 453 are made of a material containing Cu.

The outer end wiring 453 is configured as a common end wiring for the first coil 43A and the second coil 43B. The outer end wiring 453 may be provided for each of the first coil 43A and the second coil 43B.

The second coil wiring 451 is formed in the same winding direction as the first coil wiring 441 shown in FIG. 11 in a plan view. In one example, the number of turns of the second coil wiring 451 is the same as the number of turns of the first coil wiring 441. In addition, the number of turns of the second coil wiring 451 and the number of turns of the first coil wiring 441 may be different from each other.

As shown in FIG. 13, the primary coil 42 and the secondary coil 43 of the transformer 41 are disposed to be opposite to each other in the Z direction. The primary coil 42 and the secondary coil 43 arc disposed to be opposite to each other via the plurality of insulating films 430. The primary coil 42 is configured as a conductive layer buried in one insulating film 430. In one example, the primary coil 42 is buried in the insulating film 430. The secondary coil 43 is configured as a conductive layer buried in one insulating film 430, which is different from the insulating film 430 in which the primary coil 42 is buried, among the plurality of insulating films 430. In one example, the secondary coil 43 is buried in the insulating film 430 that is separated from the insulating film 430, in which the primary coil 42 is buried, in the Z direction. In the Z direction, the secondary coil 43 is located farther from the semiconductor substrate 410 than the primary coil 42. In other words, it can be said that the secondary coil 43 is located above the primary coil 42. It can also be said that the primary coil 42 is disposed to be closer to the semiconductor substrate 410 than the secondary coil 43.

As shown in FIGS. 9, 10, and 12, the transformer chip 40 may include the dummy wiring 460. The dummy wiring 460 is provided around the secondary coil 43 of the transformer 41. In addition, the dummy wiring 460 may be omitted.

The dummy wiring 460 includes a first dummy wiring 461, a second dummy wiring 462, and a third dummy wiring 463. The first dummy wiring 461, the second dummy wiring 462, and the third dummy wiring 463 are made of a material containing one or more appropriately selected from Ti, TiN, Au, Ag, Cu, Al, and W.

As shown in FIGS. 9 and 10, the first dummy wiring 461 is provided in a region between the first coil 43A and the second coil 43B of the secondary coil 43 in the X direction in a plan view. The first dummy wiring 461 is formed in a pattern different from that of the secondary coil 43. The first dummy wiring 461 may be electrically connected to the outer end wiring 453. The first dummy wiring 461 may have a wiring pattern formed so that no current flows. The first dummy wiring 461 may be electrically connected to at least one of the four outer end wirings 453 shown in

FIG. 9.

As shown in FIG. 9 and FIG. 10, the third dummy wiring 463 is formed so as to surround the secondary coil 43 (the first coil 43A and the second coil 43B) of the transformer 41 in a plan view. The third dummy wiring 463 is electrically connected to the first dummy wiring 461. The second dummy wiring 462 is formed so as to surround the third dummy wiring 463 in a plan view. The second dummy wiring 462 is independent from the secondary coil 43. In other words, the second dummy wiring 462 is not electrically connected to the secondary coil 43.

As shown in FIG. 14, the first dummy wiring 461 is disposed in the same position as the second dummy wiring 462 and the third dummy wiring 463 in the Z direction. As shown in FIG. 13, the second dummy wiring 462 and the third dummy wiring 463 are disposed in the same position as the secondary coil 43 in the Z direction. Therefore, the first dummy wiring 461, the second dummy wiring 462, and the third dummy wiring 463 are disposed in the same position as the secondary coil 43 in the Z direction.

By making the first dummy wiring 461 have the same voltage as the secondary coil 43, a voltage drop between the secondary coil 43 and the first dummy wiring 461 can be suppressed. Therefore, an electric field concentration on the secondary coil 43 can be suppressed. By making the third dummy wiring 463 have the same voltage as the secondary coil 43, a voltage drop between the secondary coil 43 and the third dummy wiring 463 can be suppressed. Therefore, an electric field concentration on the secondary coil 43 can be suppressed. The second dummy wiring 462 can suppress an increase in an electric field strength around the secondary coil 43.

As shown in FIGS. 9, FIG. 10, and FIG. 12, the transformer chip 40 may include a fourth dummy wiring 464. In addition, the fourth dummy wiring 464 may be omitted. The fourth dummy wiring 464 is made of a material containing one or more appropriately selected from Ti, TiN, Au, Ag, Cu, Al, and W. The fourth dummy wiring 464 is disposed between the secondary coil 43 and the first electrode pad 44 in a plan view. The fourth dummy wiring 464 extends along the X direction. The fourth dummy wiring 464 is formed along the plurality of first electrode pads 44 in a plan view. The fourth dummy wiring 464 may include a plurality of wirings. The fourth dummy wiring 464 is electrically independent from the secondary coil 43. In other words, the fourth dummy wiring 464 is not electrically connected to the secondary coil 43. The fourth dummy wiring 464 separates the plurality of first electrode pads 44 from the secondary coil 43.

As shown in FIG. 13 and FIG. 14, the transformer chip 40 includes a passivation film 470. The passivation film 470 is formed on the top surface 421 of the insulating layer 420. The passivation film 470 is a film that protects the insulating layer 420. The passivation film 470 is a surface protection film for the transformer chip 40. The passivation film 470 is made of a material containing, for example, silicon oxide or silicon nitride. Examples of the material containing silicon nitride may include SiN and SiCN. The passivation film 470 constitutes the chip top surface 401 of the transformer chip 40.

The first electrode pad 44 and the second electrode pad 45 are covered with the passivation film 470. The passivation film 470 has an opening that exposes portions of the first electrode pad 44 and the second electrode pad 45. As a result, the first electrode pad 44 has an exposed surface for connecting a wire. In addition, the second electrode pad 45 has an exposed surface for connecting a wire.

The transformer chip 40 may include a resin layer 472 formed on the passivation film 470. The resin layer 472 is made of a material containing, for example, polyimide (PI). The resin layer 472 is separated into an inner resin layer and an outer resin layer by a separation groove. The separation groove is formed so as to surround the transformer 41 in a plan view. The resin layer 472 may include a first opening that exposes the first electrode pad 44, and a second opening that exposes the second electrode pad 45.

### (Rectifier Chip)

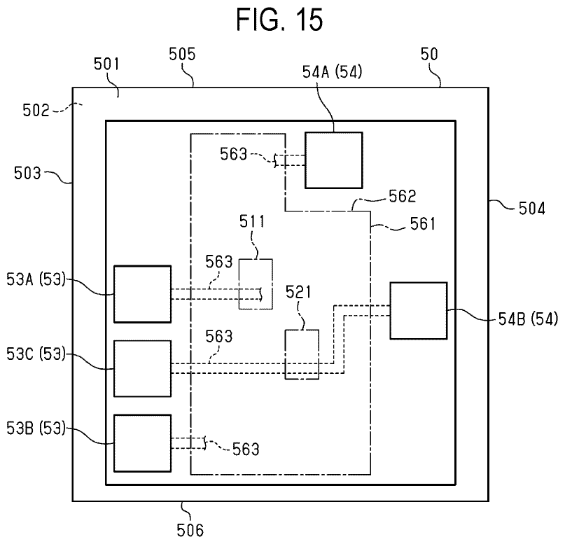

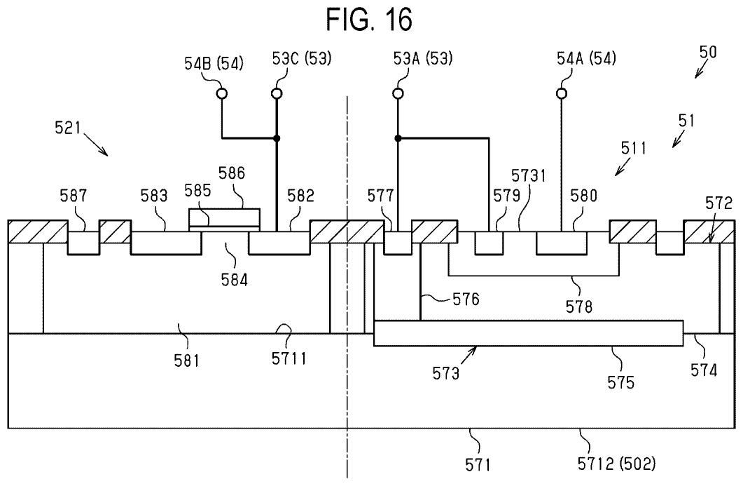

The rectifier chip 50 will be described with reference to FIG. 15 and FIG. 16. FIG. 15 is a schematic plan view showing the rectifier chip 50. FIG. 16 is a schematic cross-sectional view of the rectifier chip 50 of FIG. 15. In FIG. 16, the transistors 511 and 521 are shown as circuit elements related to a connection with the switch circuit 60 and the load 80. In FIG. 15 and FIG. 16, to make the explanation easier to understand, the transistor 511 included in the rectifier circuit 51 shown in FIG. 2 is shown, and the transistor 512 and the resistor 551 between the transistor 511 and the first output pad 54A are omitted.

The rectifier chip 50 may have a rectangular shape in a plan view. The rectifier chip 50 includes the chip top surface 501 and the chip bottom surface 502 on the opposite side of the chip top surface 501. The rectifier chip 50 includes the plurality of chip side surfaces 503 to 506 that connect the chip top surface 501 and the chip bottom surface 502. The chip bottom surface 502 is formed of a semiconductor substrate 571. The input pads 53 and the output pads 54 are exposed from the chip top surface 501. The first chip side surface 503 and the second chip side surface 504 form both end surfaces of the transformer chip 40 in the Y direction. The third chip side surface 505 and the fourth chip side surface 506 form both end surfaces of the transformer chip 40 in the X direction.

The rectifier chip 50 includes a plurality of input pads 53 and a plurality of output pads 54 on the chip top surface 501. The chip top surface 501 corresponds to a “first main surface” of the rectifier chip 50. The plurality of input pads 53 are disposed to be closer to the chip side surface 503 than the plurality of output pads 54. The plurality of input pads 53 are arranged along the chip side surface 503. It can be said that the plurality of input pads 53 are arranged in the Y direction.

The plurality of input pads 53 include a first input pad 53A, a second input pad 53B, and a third input pad 53C. The third input pad 53C corresponds to the third input pad 53C shown in FIG. 2. The first input pad 53A corresponds to the first input pad 53A shown in FIG. 2. The second input pad 53B corresponds to the second input pad 53B shown in FIG. 2.

The plurality of output pads 54 include a first output pad 54A and a second output pad 54B. The first output pad 54A is disposed to be closer to the third chip side surface 505 than the second output pad 54B. The second output pad 54B is disposed to be closer to the second chip side surface 504 than the first output pad 54A.

As shown in FIG. 15, the rectifier chip 50 includes a circuit region 561. In FIG. 15, the circuit region 561 is indicated by a one-dot chain line. The circuit region 561 is a region in which the elements of the rectifier circuit 51 shown in FIG. 2 are disposed.

The circuit region 561 is disposed in a central portion of the rectifier chip 50 in the Y direction. The circuit region 561 has a rectangular shape in which a length in the X direction is longer than a length in the Y direction. A portion of the circuit region 561 is recessed. In one example, the circuit region 561 includes a recess 562 near a corner between the third chip side surface 505 and the second chip side surface 504. The recess 562 may be a portion of the circuit region 561 near the third chip side surface 505 and near the second chip side surface 504. The first output pad 54A is disposed in the recess 562 of the circuit region 561. The circuit region 561 is partially recessed, and the first output pad 54A is disposed in a recessed space of the circuit region 561.

As shown in FIG. 15, the transistors 511 and 521 are disposed in the circuit region 561. In FIG. 15, the transistors 511 and 521 are indicated by one-dot chain lines. The transistors 511 and 521 are elements included in the rectifier circuit 51 shown in FIG. 2. In addition, the shapes and positions of the transistors 511 and 521 shown in FIG. 15 are merely examples and are not intended to specify the shapes or positions.

In FIG. 15, a plurality of wirings 563 connecting the circuit region 561 to the plurality of input pads 53 and the plurality of output pads 54 are indicated by broken lines. In addition, the plurality of wirings 563 are intended to schematically show connections among the circuit region 561, the plurality of input pads 53, and the plurality of output pads 54, and are not necessarily intended to show connections by wirings.

FIG. 16 shows an example of a cross-sectional structure of the rectifier chip 50. FIG. 16 schematically shows a cross-sectional structure of the circuit region 561 shown in FIG. 15, more specifically, cross-sectional structures of the transistors 511 and 521. In FIG. 16, the cross-sectional structure of the transistor 511 is shown on a right-hand side of a one-dot chain line, and the cross-sectional structure of the transistor 521 is shown on a left-hand side of the one-dot chain line.

The rectifier chip 50 includes the semiconductor substrate 571. The semiconductor substrate 571 may be a substrate formed from a material containing Si. In one example, the semiconductor substrate 571 may be a Si substrate. In one example, the semiconductor substrate 571 may contain impurities of a first conductivity type (in one example, p-type). The semiconductor substrate 571 includes a substrate top surface 5711 and a substrate bottom surface 5712 on an opposite side of the substrate top surface 5711. The substrate top surface 5711 corresponds to a first surface of the semiconductor substrate 571. The substrate bottom surface 5712 may constitute the chip bottom surface 502 of the rectifier chip 50.

The rectifier chip 50 includes a semiconductor layer 572 provided on the semiconductor substrate 571. The semiconductor layer 572 may be an epitaxial layer, for example. The semiconductor layer 572 may be made of a material containing Si. The semiconductor layer 572 may contain predetermined impurities. For example, the semiconductor layer 572 may contain impurities of a first conductivity type (in one example, p-type).

The semiconductor layer 572 is provided with a first semiconductor region 573. The first semiconductor region 573 is a region in which the transistor 511 is formed. The first semiconductor region 573 may contain impurities of a second conductivity type (in one example, n-type).

The first semiconductor region 573 may include an epitaxial layer 574, a buried layer 575 disposed between the epitaxial layer 574 and the semiconductor substrate 571, a collector contact region 576 in contact with the buried layer 575, and a contact region 577 provided in the collector contact region 576. The first semiconductor region 573 may be a collector region.

A base region 578 is disposed on a surface 5731 of the first semiconductor region 573. The base region 578 may be a region containing impurities of the first conductivity type, for example. A base contact 579 and an emitter region 580 are disposed in the base region 578. The base contact 579 may be a region containing impurities of the first conductivity type, for example. The emitter region 580 may be a region containing impurities of the second conductivity type, for example.

The rectifier chip 50 includes a well region 581 provided in the semiconductor layer 572. The well region 581 is a region in which the transistor 521 is formed. The well region 581 may be a region containing impurities of the first conductivity type, for example. The rectifier chip 50 includes a source region 582 and a drain region 583. The source region 582 and the drain region 583 are provided in a surface portion of the well region 581. The source region 582 and the drain region 583 may contain impurities of the second conductivity type. The source region 582 and the drain region 583 of the second conductivity type are in contact with the well region 581. In one example, the well region 581 of the first conductivity type is in contact with the semiconductor substrate 571 of the first conductivity type. The source region 582 and the drain region 583 of the second conductivity type can be said to be in contact with the semiconductor substrate 571 of the first conductivity type. At least one of the source region 582 or the drain region 583 can be said to be a second semiconductor region of the second conductivity type in contact with the semiconductor substrate 571 of the first conductivity type.

The well region 581 includes a channel region 584 between the source region 582 and the drain region 583. The rectifier chip 50 includes a gate insulating film 585 and a gate electrode 586 on the channel region 584. The gate electrode 586 faces the channel region 584 with the gate insulating film 585 interposed therebetween. The gate insulating film 585 is made of an insulating material such as SiO₂ or SiN (silicon nitride). The gate electrode 586 is made of a material containing polysilicon having conductivity. The rectifier chip 50 includes a back gate region 587. The back gate region 587 is provided on a surface portion of the well region 581. In one example, the back gate region 587 may include impurities of the second conductivity type.

The emitter region 580 of the transistor 511 is electrically connected to the first output pad 54A. The base region 578 and the first semiconductor region (the collector region) 573 of the transistor 511 are electrically connected to the first input pad 53A (the third input pad 53C). The source region 582 of the transistor 521 is electrically connected to the third input pad 53C and the second output pad 54B.

### Operation of First Embodiment

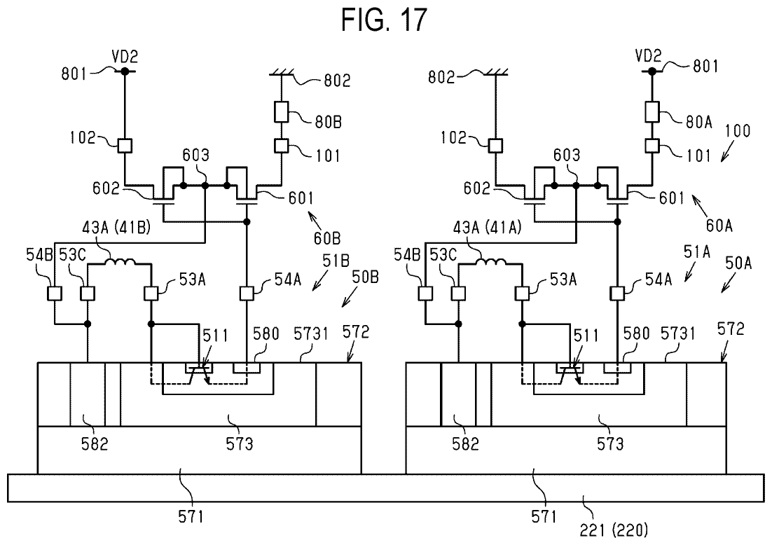

Next, an operation of the insulation switch 100 according to the first embodiment will be described. FIG. 17 is a schematic cross-sectional view showing a connection state between the insulation switch 100 according to the first embodiment and the loads 80A and 80B. FIG. 17 shows the first rectifier chip 50A and the second rectifier chip 50B included in the insulation switch 100, and the first switch circuit 60A and the second switch circuit 60B connected thereto. In addition, FIG. 17 shows the cross-sectional structure of the rectifier chips 50A and 50B shown in FIG. 16 in a simplified manner.

As shown in FIG. 17, the first load 80A and the second load 80B are connected to the insulation switch 100. The first load 80A is a load driven in a sink mode. The drive voltage VD2 is supplied to the first terminal of the first load 80A, and the second terminal of the first load 80A is connected to the first connection terminal 101. The first load 80A is driven by the first switch circuit 60A that is turned on/off by the first rectifier circuit 51A of the first rectifier chip 50A. The first switch circuit 60A is connected between the first connection terminal 101 and the second connection terminal 102. The second connection terminal 102 is connected to the low potential terminal 802. In one example, the voltage of the low potential terminal 802 is 0 V. In one example, the drive voltage VD2 is 36 V.

The first switch circuit 60A includes the first switch element 601 and the second switch element 602. The drain terminal of the first switch element 601 is connected to the first connection terminal 101, and the drain terminal of the second switch element 602 is connected to the second connection terminal 102. The source terminal of the first switch element 601 and the source terminal of the second switch element 602 are connected to each other and to the second output pad 54B of the first rectifier chip 50A. The gate terminal of the first switch element 601 and the gate terminal of the second switch element 602 are connected to each other and to the first output pad 54A of the first rectifier chip 50A. In the first rectifier chip 50A, the first coil 43A of the first transformer 41A is connected between the first input pad 53A and the third input pad 53C.

The first rectifier chip 50A includes the semiconductor substrate 571 and the semiconductor layer 572 provided on the semiconductor substrate 571. The semiconductor layer 572 is provided with the first semiconductor region 573 and the second semiconductor region 582. The first semiconductor region 573 is provided with the transistor 511. The emitter region 580 of the transistor 511 is electrically connected to the first output pad 54A. The second semiconductor region 582 may be, for example, the source region 582 of the transistor 521 shown in FIG. 16. The second semiconductor region 582 is electrically connected to the third input pad 53C and the second output pad 54B.

The first rectifier circuit 51A of the first rectifier chip 50A generates the drive signal S2 in response to the first induced current I21 generated in the first coil 43A of the first transformer 41A. The drive signal S2 is supplied from the first output pad 54A to the gate terminal of the first switch element 601 and the gate terminal of the second switch element 602. The first switch element 601 and the second switch element 602 are turned on or off in response to the drive signal S2 supplied to their respective gate terminals.

The second load 80B is a load driven in a source mode. The first terminal of the second load 80B is connected to the first connection terminal 101, and the second terminal of the second load 80B is connected to the low potential terminal 802. The second load 80B is driven by the second switch circuit 60B that is turned on/off by the second rectifier chip 50B. The second switch circuit 60B is connected between the first output pad 54A and the second output pad 54B. The drive voltage VD2 is supplied to the second output pad 54B.

The second switch circuit 60B includes the first switch element 601 and the second switch element 602. The drain terminal of the first switch element 601 is connected to the first connection terminal 101, and the drain terminal of the second switch element 602 is connected to the second connection terminal 102. The source terminal of the first switch element 601 and the source terminal of the second switch element 602 are connected to each other and to the second output pad 54B of the second rectifier chip 50B. The gate terminal of the first switch element 601 and the gate terminal of the second switch element 602 are connected to each other and to the first output pad 54A of the second rectifier chip 50B. In the second rectifier chip 50B, the first coil 43A of the second transformer 41B is connected between the first input pad 53A and the third input pad 53C.

The second rectifier chip 50B includes the semiconductor substrate 571 and the semiconductor layer 572 provided on the semiconductor substrate 571. The semiconductor layer 572 is provided with the first semiconductor region 573 and the second semiconductor region 582. The first semiconductor region 573 is provided with the transistor 511. The emitter region 580 of the transistor 511 is electrically connected to the first output pad 54A. In one example, the second semiconductor region 582 may be the source region 582 of the transistor 521 shown in FIG. 16. The second semiconductor region 582 is electrically connected to the third input pad 53C and the second output pad 54B.

The second rectifier circuit 51B of the second rectifier chip 50B generates the drive signal S2 in response to the first induced current I21 generated in the first coil 43A of the second transformer 41B. The drive signal S2 is supplied from the first output pad 54A to the gate terminal of the first switch element 601 and the gate terminal of the second switch element 602. The first switch element 601 and the second switch element 602 are turned on or off in response to the drive signal S2 supplied to their respective gate terminals.

### Comparative Example

Here, an insulation switch 100X according to a comparative example for the insulation switch 100 according to the first embodiment will be described. The same names and symbols are used for components of the insulation switch 100X according to the comparative example that are similar to those of the insulation switch 100 according to the first embodiment.

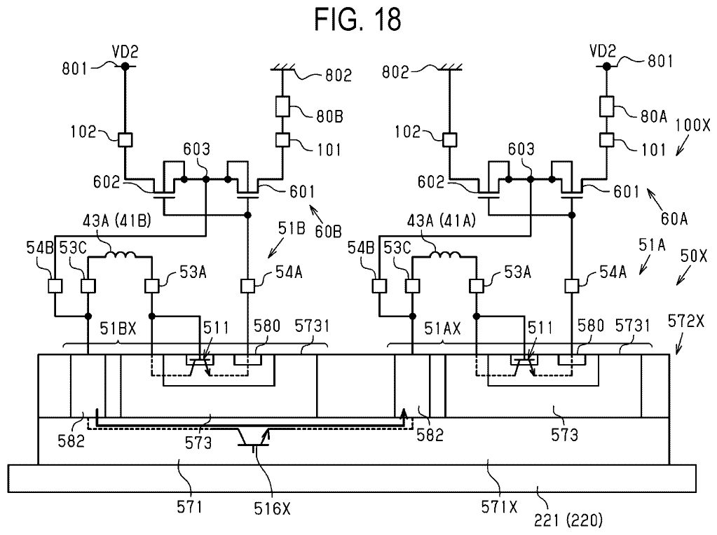

FIG. 18 shows a connection state between the insulation switch 100X according to the comparative example and the loads 80A and 80B. The insulation switch 100X according to the comparative example includes one rectifier chip 50X. The rectifier chip 50X of the comparative example includes the first rectifier circuit 51A and the second rectifier circuit 51B.

The rectifier chip 50X of the comparative example includes a semiconductor substrate 571X and a semiconductor layer 572X provided on the semiconductor substrate 571X. The semiconductor layer 572X includes a first region 51AX in which the first rectifier circuit 51A is provided, and a second region 51BX in which the second rectifier circuit 51B is provided. The semiconductor substrate 571X is provided as a common substrate for the first rectifier circuit 51A and the second rectifier circuit 51B.

Both the first region 51AX and the second region 51BX include the first semiconductor region 573 and the second semiconductor region 582. The emitter region 580 of the transistor 511 provided in the first semiconductor region 573 is electrically connected to the first output pad 54A. The second semiconductor region 582 is electrically connected to the third input pad 53C and the second output pad 54B.

In the insulation switch 100X according to this comparative example, the first switch circuit 60A and the second switch circuit 60B are controlled in the same manner as the insulation switch 100 according to the above-described first embodiment. That is, the first rectifier circuit 51A controls the first switch circuit 60A by rectifying the first induced current I21 flowing through the secondary coil 43 of the first transformer 41A. Similarly, the second rectifier circuit 51B controls the second switch circuit 60B by rectifying the first induced current I21 flowing through the secondary coil 43 of the second transformer 41B.

When the first switch circuit 60A is turned on, the first load 80A is connected between the high potential terminal 801, which is the supply source of the drive voltage VD2, and the low potential terminal 802. Then, a node 603, which is a connection point between the first switch element 601 and the second switch element 602, becomes approximately equal to the potential of the low potential terminal 802. In other words, the potential of the second connection terminal 102 of the insulation switch 100X becomes equal to the potential of the low potential terminal 802.

Similarly, when the second switch circuit 60B is turned on, the second load 80B is connected between the high potential terminal 801, which is the supply source of the drive voltage VD2, and the low potential terminal 802. Then, the node 603 between the first switch element 601 and the second switch element 602 becomes approximately equal to the potential of the drive voltage VD2. That is, the potential of the second connection terminal 102 of the insulation switch 100X becomes equal to the potential of the drive voltage VD2.

The rectifier chip 50X of this comparative example can be connected to the loads 80A and 80B of different drive types. As shown in FIG. 2, the rectifier circuit 51 is configured to rectify the induced current I21 flowing through the secondary coil 43 of the transformer 41 and output the drive signal S2. Therefore, the rectifier circuit 51 does not require a drive voltage to be supplied from outside. For this reason, the rectifier chip 50X of the comparative example has the semiconductor substrate 571X in a floating state.

The rectifier chip 50X of this comparative example includes a parasitic transistor 516X between the first rectifier circuit 51A and the second rectifier circuit 51B. The parasitic transistor 516X is an npn-type bipolar transistor with the semiconductor substrate 571X of a first conductivity type (p-type) as a base and the second semiconductor region 582 of the first and second rectifier circuits 51A and 51B as an emitter and a collector of a second conductivity type. Explaining according to the connection state of the loads 80A and 80B, the parasitic transistor 516X has the second semiconductor region 582 of the second rectifier circuit 51B as the collector of the second conductivity type (n-type) and the second semiconductor region 582 of the first rectifier circuit 51A as the emitter of the second conductivity type.

In this state, when a fluctuation occurs in the driving voltage VD2, a trigger current is generated in the semiconductor substrate 571X. As described above, since the semiconductor substrate 571X is in a floating state, a current flows to the base of the parasitic transistor 516X, which is the semiconductor substrate 571X. Then, a collector current corresponding to a base current flows through the parasitic transistor 516X. As a result, a current path is formed from the second semiconductor region 582 of the second rectifier circuit 51B toward the second semiconductor region 582 of the first rectifier circuit 51A via the semiconductor substrate 571X. The current flowing through this parasitic transistor 516X may continue until the supply of the drive voltage VD2 is stopped. As described above, latch-up may occur in the insulation switch 100X according to the comparative example.

In contrast, the insulation switch 100 according to the first embodiment includes the first rectifier chip 50A and the second rectifier chip 50B. The first rectifier chip 50A and the second rectifier chip 50B are disposed to be spaced apart from each other. In other words, the semiconductor substrate 571 of the first rectifier chip 50A and the semiconductor substrate 571 of the second rectifier chip 50B are physically separated from each other and are not electrically connected. As described above, the insulation switch 100 according to the first embodiment does not include a parasitic transistor between the second semiconductor region 582 of the first rectifier circuit 51A and the second semiconductor region 582 of the second rectifier circuit 51B. Therefore, the insulation switch 100 according to the first embodiment can suppress occurrence of latch-up. Therefore, operations of the insulation switch 100 according to the first embodiment can be stabilized.

The first rectifier chip 50A and the second rectifier chip 50B are bonded to the second die pad 221 by the bonding material SD3. When the bonding material SD3 having insulation property is used, the semiconductor substrate 571 of the first rectifier chip 50A and the semiconductor substrate 571 of the second rectifier chip 50B are not electrically connected to each other. Therefore, the insulation switch 100 according to the first embodiment can suppress occurrence of latch-up. On the other hand, when the bonding material SD3 having conductivity is used, the semiconductor substrate 571 of the first rectifier chip 50A and the semiconductor substrate 571 of the second rectifier chip 50B are electrically connected via the bonding material SD3 and the second die pad 221. However, even when a voltage change occurs in the semiconductor substrate 571 of the second rectifier chip 50B, for example, due to a fluctuation in the drive voltage VD2, the voltage change hardly influences the semiconductor substrate 571 of the first rectifier chip 50A. Therefore, the insulation switch 100 according to the first embodiment can suppress occurrence of latch-up. Therefore, operations of the insulation switch 100 according to the first embodiment can be stabilized.

### Effects of First Embodiment

The insulation switch 100 according to the first embodiment achieves the effects set forth below.

(1-1) The insulation switch 100 includes the semiconductor device 20 to which the first switch circuit 60A and the second switch circuit 60B are connected. The semiconductor device 20 includes the first transformer 41A, the second transformer 41B, the first rectifier chip 50A, and the second rectifier chip 50B. The semiconductor device 20 includes the second die pad 221 on which the first rectifier chip 50A and the second rectifier chip 50B are mounted. The first transformer 41A includes the primary coil 42 and the secondary coil 43. The second transformer 41B includes the primary coil 42 and the secondary coil 43. The first rectifier chip 50A includes the first rectifier circuit 51A that is electrically connected to the secondary coil 43 of the first transformer 41A and controls the first switch circuit 60A by rectifying the induced current I21 flowing through the secondary coil 43 (the first coil 43A) of the first transformer 41A. The second rectifier chip 50B includes the second rectifier circuit 51B that is electrically connected to the secondary coil 43 of the second transformer 41B and controls the second switch circuit 60B by rectifying the induced current I22 flowing through the secondary coil 43 (the first coil 43A) of the second transformer 41B.

The first rectifier chip 50A and the second rectifier chip 50B each include the first output pad 54A, the second output pad 54B, the semiconductor substrate 571 of a first conductivity type including the substrate top surface 5711, the first semiconductor region 573 of a second conductivity type disposed on the substrate top surface 5711, the transistor 511 provided in the first semiconductor region 573 and electrically connected to the first output pad 54A, and the second semiconductor region 582 of a second conductivity type provided at a position spaced apart from the transistor 511 in the first semiconductor region 573 and electrically connected to the second output pad 54B. The second semiconductor region 582 is in contact with the semiconductor substrate 571. The first rectifier chip 50A and the second rectifier chip 50B are disposed to be spaced apart from each other.

In the insulation switch 100 according to the first embodiment, the semiconductor substrate 571 of the first rectifier chip 50A and the semiconductor substrate 571 of the second rectifier chip 50B are physically separated from each other and not electrically connected to each other. As described above, the insulation switch 100 according to the first embodiment does not include a parasitic transistor between the second semiconductor region 582 of the first rectifier circuit 51A and the second semiconductor region 582 of the second rectifier circuit 51B. Therefore, the insulation switch 100 according to the first embodiment can suppress occurrence of latch-up. Therefore, operations of the insulation switch 100 according to the first embodiment can be stabilized.

(1-2) The first rectifier chip 50A and the second rectifier chip 50B are bonded to the second die pad 221 by the bonding material SD3. When the bonding material SD3 having insulation property is used, the semiconductor substrate 571 of the first rectifier chip 50A and the semiconductor substrate 571 of the second rectifier chip 50B are not electrically connected to each other. Therefore, the insulation switch 100 according to the first embodiment can suppress occurrence of latch-up. On the other hand, when the bonding material SD3 having conductivity is used, the semiconductor substrate 571 of the first rectifier chip 50A and the semiconductor substrate 571 of the second rectifier chip 50B are electrically connected to each other via the bonding material SD3 and the second die pad 221. However, even when a voltage change occurs in the semiconductor substrate 571 of the second rectifier chip 50B, for example, due to a fluctuation in the drive voltage VD2, the voltage change hardly influences the semiconductor substrate 571 of the first rectifier chip 50A. Therefore, the insulation switch 100 according to the first embodiment can suppress occurrence of latch-up. Therefore, operations of the insulation switch 100 according to the first embodiment can be stabilized.

(1-3) The insulation switch 100 includes the semiconductor device 20 to which the first to fourth switch circuits 60A to 60D are connected. The semiconductor device 20 includes the first to fourth rectifier chips 50A to 50D. The first to fourth rectifier chips 50A to 50D are mounted on the second die pad 221. The first to fourth rectifier chips 50A to 50D are disposed to be spaced apart from one another. The first to fourth rectifier chips 50A to 50D include the first to fourth rectifier circuits 51A to 51D that control the on/off of the first to fourth switch circuits 60A to 60D by rectifying the induced current I21 flowing through the secondary coil 43 (the first coil 43A) of the first to fourth transformers 41A to 41D. This insulation switch 100 can individually control the first to fourth switch circuits 60A to 60D. As a result, the operations of the first to fourth rectifier chips 50A to 50D can be stabilized.

### Second Embodiment

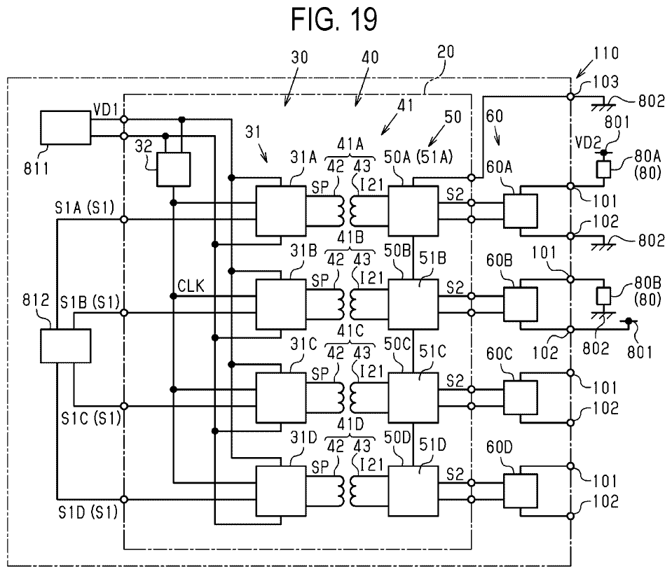

An insulation switch 110 according to a second embodiment will be described with reference to FIG. 19 to FIG. 23. Constituent elements of the insulation switch 110 according to the second embodiment that are common to the insulation switch 100 according to the first embodiment are denoted by the same reference numerals as in the first embodiment, and explanation thereof will be omitted.

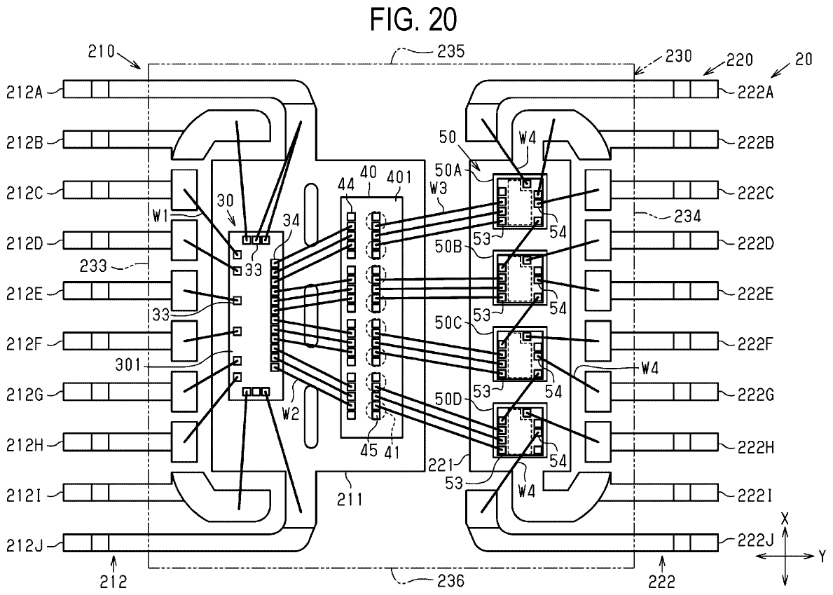

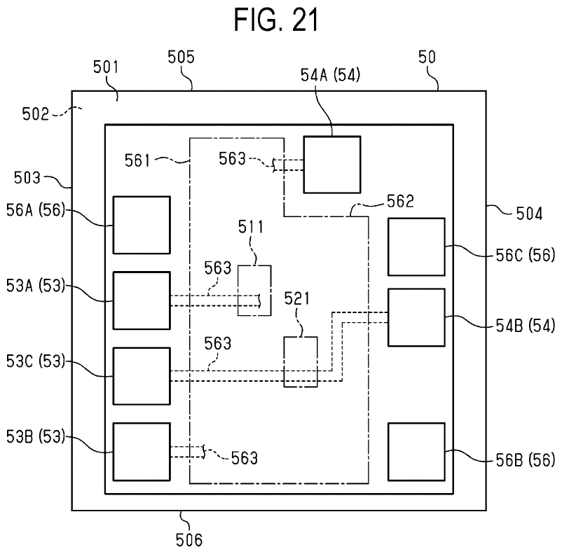

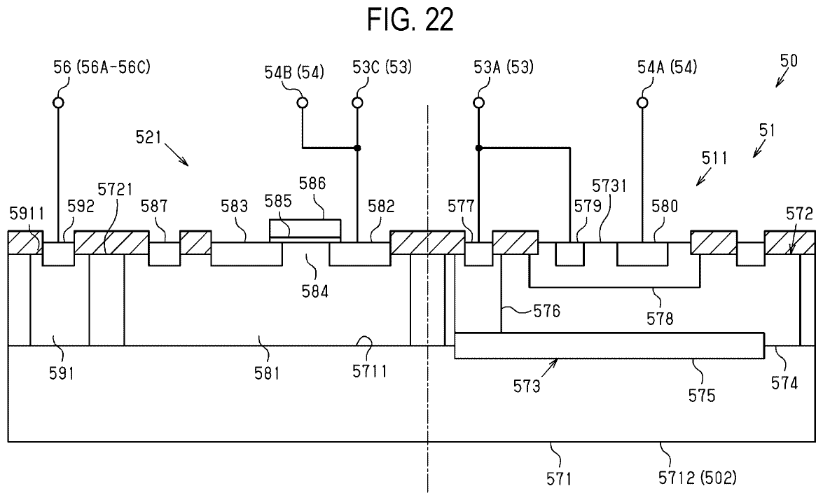

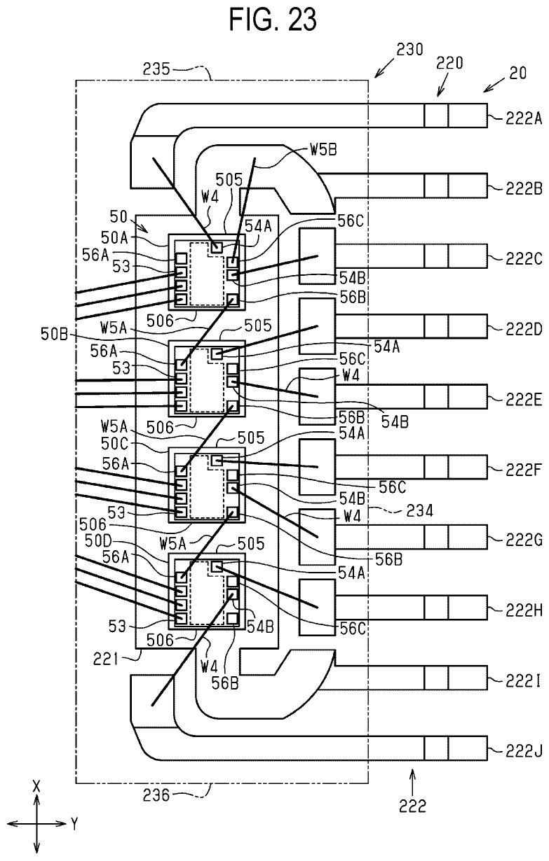

FIG. 19 is a block circuit diagram showing a schematic configuration of the insulation switch 110 according to the second embodiment. FIG. 20 is a schematic plan view showing an example of the semiconductor device 20 of FIG. 19. FIG. 21 is a schematic plan view showing the rectifier chip 50 of FIG. 20. FIG. 22 is a schematic cross-sectional view of the rectifier chip 50 of FIG. 21. FIG. 23 is a schematic plan view showing an enlarged portion of the semiconductor device 20 of FIG. 20.

### (Schematic Configuration of Insulation Switch)

As shown in FIG. 20, in the insulation switch 110 according to the second embodiment, the first rectifier chip 50A is electrically connected to the second lead terminal 222B of the insulation switch 110. The second lead terminal 222B is electrically connected to a third connection terminal 103 shown in FIG. 19. The third connection terminal 103 may be provided as a terminal of a device including the insulation switch 110. The device including the insulation switch 110 may include a plurality of third connection terminals 103.

### (Configuration of Rectifier Chip)

As shown in FIG. 21, the rectifier chip 50 according to the second embodiment is mainly different from the rectifier chip 50 according to the first embodiment in that the former includes a substrate connection pad 56.

The substrate connection pad 56 is provided on the chip top surface 501 having the circuit region 561. As shown in FIG. 22, the substrate connection pad 56 is electrically connected to the semiconductor substrate 571 of the rectifier chip 50. The rectifier chip 50 includes a connection region 591 provided in the semiconductor layer 572. In one example, the connection region 591 may contain impurities of a first conductivity type (p-type). The connection region 591 reaches from an upper surface 5721 of the semiconductor layer 572 to the semiconductor substrate 571. The connection region 591 is in contact with the semiconductor substrate 571. The connection region 591 is electrically connected to the semiconductor substrate 571. A contact region 592 is provided on an upper surface 5911 of the connection region 591. In one example, the contact region 592 may contain impurities of the first conductivity type. The contact region 592 is electrically connected to the substrate connection pad 56. Therefore, the semiconductor substrate 571 is electrically connected to the substrate connection pad 56 via the connection region 591 and the contact region 592.

As shown in FIG. 21, the rectifier chip 50 according to the second embodiment includes a plurality of substrate connection pads 56. The plurality of substrate connection pads 56 may include a first substrate connection pad 56A and a second substrate connection pad 56B.

The first substrate connection pad 56A is disposed to be closer to the first chip side surface 503 of the rectifier chip 50 than the second substrate connection pad 56B. The second substrate connection pad 56B is disposed to be closer to the second chip side surface 504 of the rectifier chip 50 than the first substrate connection pad 56A. Therefore, the first substrate connection pad 56A and the second substrate connection pad 56B can be said to be disposed with the circuit region 561 interposed therebetween in the Y direction.

The first substrate connection pad 56A is disposed to be closer to the third chip side surface 505 of the rectifier chip 50 than the second substrate connection pad 56B. The first substrate connection pad 56A is disposed at a corner of the rectifier chip 50 that is formed by the first chip side surface 503 and the third chip side surface 505. The first substrate connection pad 56A is disposed in line with the plurality of input pads 53 of the rectifier chip 50 in the X direction. The second substrate connection pad 56B is disposed to be closer to the fourth chip side surface 506 of the rectifier chip 50 than the first substrate connection pad 56A. It can be said that the second substrate connection pad 56B is disposed at a corner of the rectifier chip 50 that is formed by the second chip side surface 504 and the fourth chip side surface 506. The second substrate connection pad 56B is disposed in line with the second output pad 54B of the rectifier chip 50 in the X direction. It can be said that the first substrate connection pad 56A and the second substrate connection pad 56B are disposed offset in the X direction. It can be said that the first substrate connection pad 56A and the second substrate connection pad 56B are disposed diagonally on the rectifier chip 50.

The plurality of substrate connection pads 56 may include a third substrate connection pad 56C. The third substrate connection pad 56C is disposed to be closer to the second chip side surface 504 of the rectifier chip 50 than the first substrate connection pad 56A. Therefore, the first substrate connection pad 56A and the third substrate connection pad 56C can be said to be disposed with the circuit region 561 interposed therebetween in the Y direction. The third substrate connection pad 56C is disposed closer to the third chip side surface 505 than the second substrate connection pad 56B. The second substrate connection pad 56B and the third substrate connection pad 56C can be said to be disposed side by side in the X direction at a location near the second chip side surface 504 in the X direction.

The third substrate connection pad 56C is disposed to be closer to the third chip side surface 505 than the second output pad 54B. The second substrate connection pad 56B is disposed to be closer to the fourth chip side surface 506 than the second output pad 54B. The second substrate connection pad 56B and the third substrate connection pad 56C can be said to be disposed with the second output pad 54B interposed therebetween. The first output pad 54A is disposed to be closer to the third chip side surface 505 than the third substrate connection pad 56C. The third substrate connection pad 56C can be said to be disposed between the first output pad 54A and the second output pad 54B.

As shown in FIG. 20 and FIG. 23, the first to fourth rectifier chips 50A to 50D are bonded to the first die pad 211. The first to fourth rectifier chips 50A to 50D are arranged along the Y direction.

As shown in FIG. 23, the fourth chip side surface 506 of the first rectifier chip 50A faces the third chip side surface 505 of the second rectifier chip 50B in the Y direction. Similarly, the fourth chip side surface 506 of the second rectifier chip 50B faces the third chip side surface 505 of the third rectifier chip 50C in the Y direction. The fourth chip side surface 506 of the third rectifier chip 50C faces the third chip side surface 505 of the fourth rectifier chip 50D in the Y direction.

The second substrate connection pad 56B of the first rectifier chip 50A is electrically connected to the first substrate connection pad 56A of the second rectifier chip 50B by a wire W5A. As a result, the semiconductor substrate 571 of the first rectifier chip 50A is electrically connected to the semiconductor substrate 571 of the second rectifier chip 50B by the connection region 591 shown in FIG. 22 and the wire W5A shown in FIG. 23. Similarly, the second substrate connection pad 56B of the second rectifier chip 50B is electrically connected to the first substrate connection pad 56A of the fourth rectifier chip 50D by the wire W5A. Further, the second substrate connection pad 56B of the third rectifier chip 50C is electrically connected to the first substrate connection pad 56A of the fourth rectifier chip 50D by the wire W5A. Therefore, the semiconductor substrates 571 of the first to fourth rectifier chips 50A to 50D are electrically connected to one another.

The second substrate connection pad 56B of the first rectifier chip 50A is disposed near the fourth chip side surface 506 of the first rectifier chip 50A. The fourth chip side surface 506 of the first rectifier chip 50A faces the third chip side surface 505 of the second rectifier chip 50B. Further, the second substrate connection pad 56B of the first rectifier chip 50A is electrically connected to the first substrate connection pad 56A of the second rectifier chip 50B by the wire W5A. The first substrate connection pad 56A of the second rectifier chip 50B is disposed near the third chip side surface 505 of the second rectifier chip 50B. Therefore, the second substrate connection pad 56B of the first rectifier chip 50A can be said to be electrically connected to the first substrate connection pad 56A of the second rectifier chip 50B, which is adjacent to the first rectifier chip 50A. In addition, the first substrate connection pad 56A of the second rectifier chip 50B can be said to be electrically connected to the second substrate connection pad 56B of the first rectifier chip 50A, which is adjacent to the second rectifier chip 50B. The same can be said between the second rectifier chip 50B and the third rectifier chip 50C and between the third rectifier chip 50C and the fourth rectifier chip 50D.

### (Connection of Substrate Connection Pads)

The third substrate connection pad 56C of the first rectifier chip 50A is electrically connected to the second lead terminal 222B by a wire W5B. The first rectifier chip 50A corresponds to a rectifier chip disposed at a first end in the X direction. Therefore, the second lead terminal 222B is electrically connected to the semiconductor substrate 571 of each of the first to fourth rectifier chips 50A to 50D. Therefore, in the insulation switch 110 according to the second embodiment, a potential of the semiconductor substrate 571 of each of the first to fourth rectifier chips 50A to 50D can be set by setting the second lead terminal 222B to a desired potential. In addition, the potential of the semiconductor substrate 571 of each of the first to fourth rectifier chips 50A to 50D can be stabilized. In one example, the second lead terminal 222B is connected to the low potential terminal 802 shown in FIG. 19. A connection destination of the second lead terminal 222B may be changed arbitrarily. The second lead terminal 222B may be electrically connected to an external terminal that provides a predetermined potential.

As shown in FIG. 23, the second lead terminal 222B is formed integrally with the second die pad 221 on which the first to fourth rectifier chips 50A to 50D are mounted. The second lead terminal 222B is electrically connected to the second die pad 221. This second die pad 221 is electrically connected to the second lead terminal 222I. Therefore, the second lead terminal 222I may be electrically connected to an external terminal that provides a predetermined potential. In addition, the two second lead terminals 222B and 222I may be electrically connected to an external terminal that provides a predetermined potential.

### Operation of Second Embodiment

The semiconductor substrates 571 of the first to fourth rectifier chips 50A to 50D are in a floating state and are physically and electrically separated from one another. By connecting the semiconductor substrates 571 of the first to fourth rectifier chips 50A to 50D to one another, voltage fluctuation of each semiconductor substrate 571 can be suppressed.

The third substrate connection pad 56C of the first rectifier chip 50A is electrically connected to the second lead terminal 222B by the wire W5B. The potential of the semiconductor substrate 571 of each of the first to fourth rectifier chips 50A to 50D can be set by setting the second lead terminal 222B to a desired potential. In one example, the second lead terminal 222B is connected to the low potential terminal 802. That is, the semiconductor substrate 571 of each of the first to fourth rectifier chips 50A to 50D is set to the potential (for example, 0 V) of the low potential terminal 802. Thus, it is possible to further stabilize the operation of the rectifier circuits 51 of the first to fourth rectifier chips 50A to 50D.

The potential of the semiconductor substrate 571 in the floating state may fluctuate due to the operation of the rectifier circuit 51 or an external factor. This may cause large voltage fluctuation in the semiconductor substrate 571 and malfunction of the rectifier circuit 51. For this reason, the operation of the rectifier circuit 51 can be further stabilized by suppressing the voltage fluctuation in the semiconductor substrate 571.

The third substrate connection pad 56C is disposed between the first output pad 54A and the second output pad 54B. The second lead terminal 222B is disposed between the second lead terminal 222A to which the first output pad 54A is connected and the second lead terminal 222C to which the second output pad 54B is connected. Therefore, in a plan view, the wire W5B does not intersect the wire W4 connected to the first output pad 54A and the wire W4 connected to the second output pad 54B. Therefore, each of the wires W4 and W5B can be easily connected. Intersection of the wires may lead to an increase in a thickness of the scaling resin 230 from the chip top surface 501 of the first rectifier chip 50A to the sealing top surface 231 of the sealing resin 230 (see FIG. 5), that is, an increase in a size of the semiconductor device. Therefore, by not intersecting the wires, the increase in the size of the semiconductor device 20 can be suppressed.

### Effects of Second Embodiment

The insulation switch 110 according to the second embodiment achieves effects set forth below in addition to the effects of the first embodiment.

(2-1) The semiconductor substrates 571 of the first to fourth rectifier chips 50A to 50D are in a floating state and are physically and electrically separated from one another. The voltage fluctuation of each semiconductor substrate 571 can be suppressed by connecting the semiconductor substrates 571 of the first to fourth rectifier chips 50A to 50D to one another.

(2-2) The third substrate connection pad 56C of the first rectifier chip 50A is electrically connected to the second lead terminal 222B by the wire W5B. The potential of the semiconductor substrate 571 of each of the first to fourth rectifier chips 50A to 50D can be set by setting the second lead terminal 222B to a desired potential. In one example, the second lead terminal 222B is connected to the low potential terminal 802. That is, the semiconductor substrate 571 of each of the first to fourth rectifier chips 50A to 50D is set to the potential (for example, 0 V) of the low potential terminal 802. Thus, it is possible to further stabilize the operation of the rectifier circuits 51 of the first to fourth rectifier chips 50A to 50D.

The potential of the semiconductor substrate 571 in the floating state may fluctuate due to the operation of the rectifier circuit 51 or an external factor. This may cause large voltage fluctuation in the semiconductor substrate 571 and malfunction of the rectifier circuit 51. For this reason, the operation of the rectifier circuit 51 can be further stabilized by suppressing the voltage fluctuation in the semiconductor substrate 571.

(2-3) The third substrate connection pad 56C is disposed between the first output pad 54A and the second output pad 54B. The second lead terminal 222B is disposed between the second lead terminal 222A to which the first output pad 54A is connected and the second lead terminal 222C to which the second output pad 54B is connected. Therefore, in a plan view, the wire W5B docs not intersect the wire W4 connected to the first output pad 54A and the wire W4 connected to the second output pad 54B. Therefore, each of the wires W4 and W5B can be easily connected. Intersection of the wires may lead to an increase in the thickness of the scaling resin 230 from the chip top surface 501 of the first rectifier chip 50A to the sealing top surface 231 of the scaling resin 230 (see FIG. 5), that is, to an increase in the size of the semiconductor device. Therefore, by not intersecting the wires, the increase in the size of the semiconductor device 20 can be suppressed.

(2-4) The second lead terminal 222B is formed integrally with the second die pad 221 on which the first to fourth rectifier chips 50A to 50D are mounted. The second lead terminal 222B is electrically connected to the second die pad 221. This second die pad 221 is electrically connected to the second lead terminal 222I. Therefore, it is sufficient to provide a predetermined potential to at least one of the second lead terminal 222B or the second lead terminal 222I. In other words, it is sufficient to connect at least one of the second lead terminal 222B or the second lead terminal 222I to the outside, which increases a degree of freedom in designing the insulation switch 110.

### Modifications of Second Embodiment

The above-described second embodiment can be modified, for example, as follows. The above-described embodiment and each of the following modifications can be combined with each other as long as no technical contradiction occurs. In the following modifications, parts common to the above-described embodiment are denoted by the same reference numerals as in the above-described embodiment, and explanation thereof will be omitted.

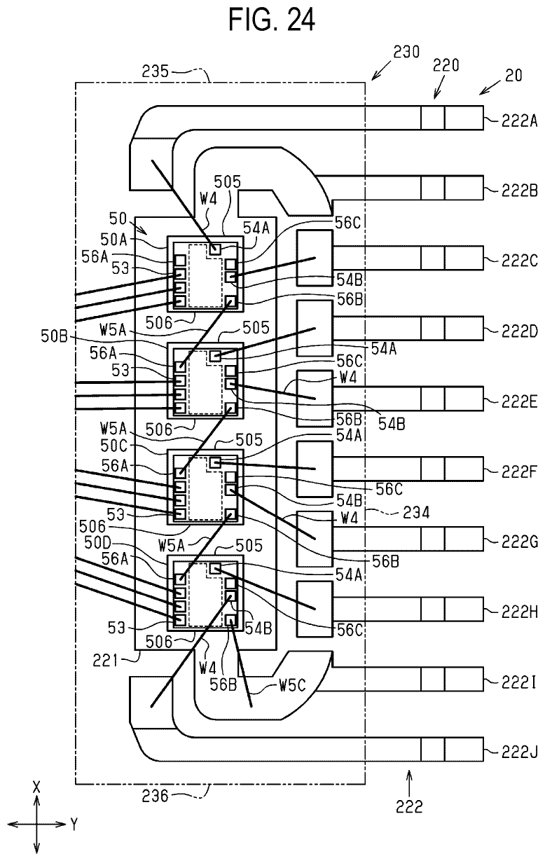

FIG. 24 to FIG. 27 are schematic plan views showing the semiconductor device 20 according to modifications. The semiconductor device 20 according to these modifications may be substituted for the semiconductor device 20 of the insulation switch 110 according to the second embodiment.

FIG. 24 to FIG. 27 show enlarged views of a portion similar to that shown in FIG. 23 showing a portion of the semiconductor device 20 according to the second embodiment.

In the semiconductor device 20 according to the modification shown in FIG. 24, the fourth rectifier chip 50D is electrically connected to the second lead terminal 222I. More specifically, the second substrate connection pad 56B of the fourth rectifier chip 50D is electrically connected to the second lead terminal 222I by a wire W5C. The fourth rectifier chip 50D corresponds to the rectifier chip disposed at the first end in the X direction. The semiconductor device 20 according to this modification achieves the same effects as the semiconductor device 20 according to the second embodiment.

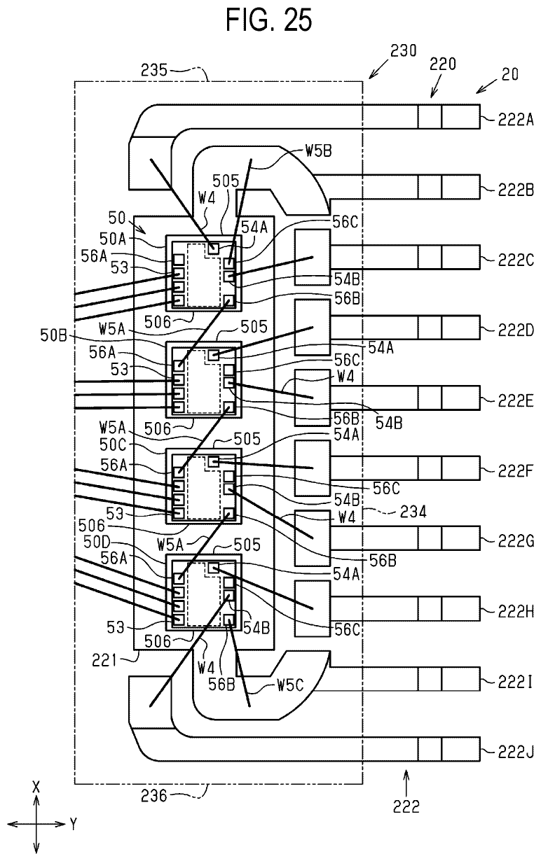

In the semiconductor device 20 according to the modification shown in FIG. 25, the first rectifier chip 50A is electrically connected to the second lead terminal 222B, and the fourth rectifier chip 50D is electrically connected to the second lead terminal 222I. More specifically, the third substrate connection pad 56C of the first rectifier chip 50A is electrically connected to the second lead terminal 222B by the wire W5B. The second substrate connection pad 56B of the fourth rectifier chip 50D is electrically connected to the second lead terminal 222I by the wire W5C. The semiconductor device 20 according to this modification achieves the same effects as the semiconductor device 20 according to the second embodiment.

In addition, in the semiconductor device 20 according to this modification, any one among the wire W5A between the first rectifier chip 50A and the second rectifier chip 50B, the wire W5A between the second rectifier chip 50B and the third rectifier chip 50C, and the wire W5A between the third rectifier chip 50C and the fourth rectifier chip 50D may be omitted.

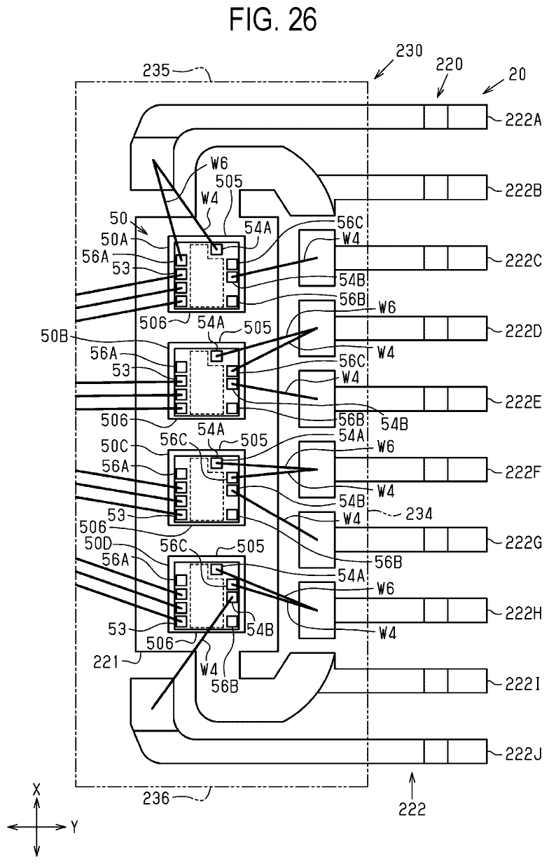

In the semiconductor device 20 according to the modification shown in FIG. 26, each of the first to fourth rectifier chips 50A to 50D is electrically connected to a second lead terminal. The first substrate connection pad 56A of the first rectifier chip 50A is electrically connected to the second lead terminal 222A by a wire W6. The first output pad 54A of the first rectifier chip 50A is electrically connected to this second lead terminal 222A by the wire W4. Further, the rectifier circuit 51 of the first rectifier chip 50A is configured to output the drive signal S2 to the first output pad 54A. Therefore, in the first rectifier chip 50A, the potential of the semiconductor substrate 571 can be made equal to a potential of the first output pad 54A, that is, the potential of the drive signal S2.

The third substrate connection pad 56C of the second rectifier chip 50B is electrically connected to the second lead terminal 222D by the wire W6. The first output pad 54A of the second rectifier chip 50B is electrically connected to this second lead terminal 222D by the wire W4. The third substrate connection pad 56C of the third rectifier chip 50C is electrically connected to the second lead terminal 222F by the wire W6. The first output pad 54A of the third rectifier chip 50C is electrically connected to this second lead terminal 222F by the wire W4. The third substrate connection pad 56C of the fourth rectifier chip 50D is electrically connected to the second lead terminal 222H by the wire W6. The first output pad 54A of the fourth rectifier chip 50D is electrically connected to this second lead terminal 222H by the wire W4. Therefore, in the second to fourth rectifier chips 50B to 50D, like the first rectifier chip 50A, the potential of the semiconductor substrate 571 can be made equal to the potential of the first output pad 54A, that is, the potential of the drive signal S2.

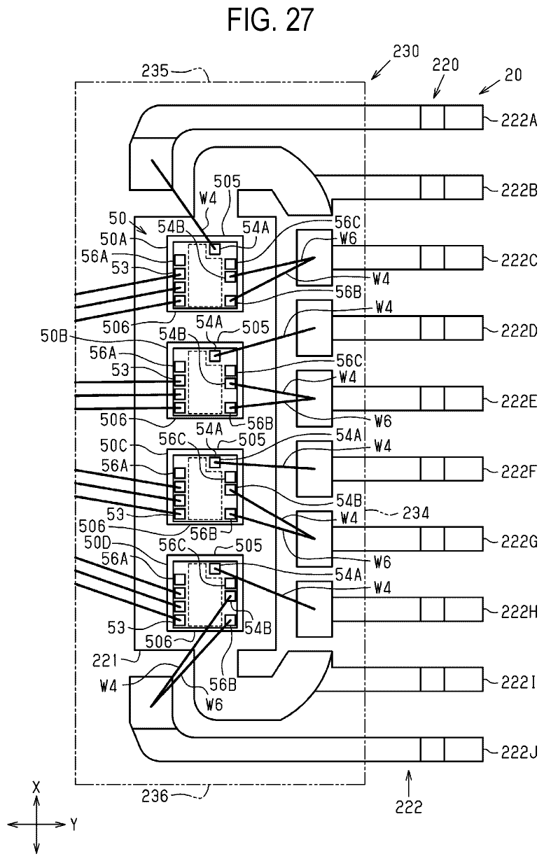

In the semiconductor device 20 according to the modification shown in FIG. 27, each of the first to fourth rectifier chips 50A to 50D is electrically connected to a second lead terminal. The second substrate connection pad 56B of the first rectifier chip 50A is electrically connected to the second lead terminal 222C by the wire W6. The second output pad 54B of the first rectifier chip 50A is electrically connected to this second lead terminal 222C by the wire W4. Further, the rectifier circuit 51 of the first rectifier chip 50A is configured to output the drive signal S2 to the second output pad 54B. Therefore, in the first rectifier chip 50A, the potential of the semiconductor substrate 571 can be made equal to a potential of the second output pad 54B.

The second substrate connection pad 56B of the second rectifier chip 50B is electrically connected to the second lead terminal 222E by the wire W6. The second output pad 54B of the second rectifier chip 50B is electrically connected to this second lead terminal 222E by the wire W4. The second substrate connection pad 56B of the third rectifier chip 50C is electrically connected to the second lead terminal 222G by the wire W6. The second output pad 54B of the third rectifier chip 50C is electrically connected to this second lead terminal 222G by the wire W4. The second substrate connection pad 56B of the fourth rectifier chip 50D is electrically connected to the second lead terminal 222J by the wire W6. The second output pad 54B of the fourth rectifier chip 50D is electrically connected to this second lead terminal 222J by the wire W4. Therefore, in the second to fourth rectifier chips 50B to 50D, the potential of the semiconductor substrate 571 can be made equal to the potential of the second output pad 54B, similar to the first rectifier chip 50A.

### Third Embodiment

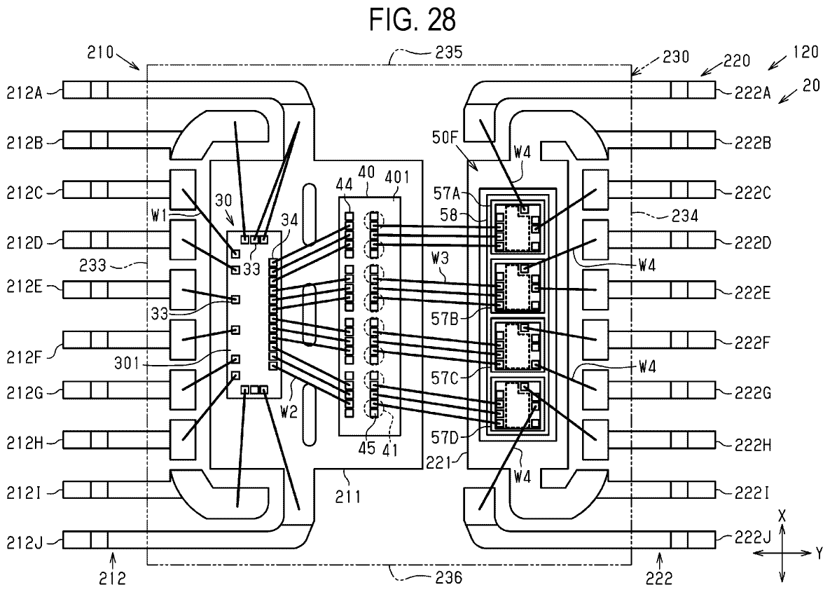

An insulation switch 120 according to a third embodiment will be described with reference to FIG. 28 to FIG. 30. With respect to the insulation switch 120 according to the third embodiment, parts common to the insulation switch 100 according to the first embodiment and the insulation switch 110 according to the second embodiment are denoted by the same reference numerals as in the above-described embodiments, and explanation thereof will be omitted.

The insulation switch 120 according to the third embodiment is different from the insulation switch 100 according to the first embodiment in the configuration of a rectifier chip 50F included in the semiconductor device 20. For this reason, parts other than the semiconductor device 20 are omitted from the drawings.

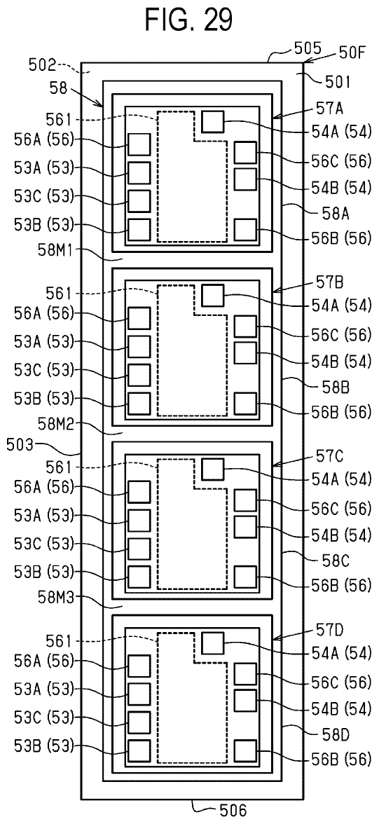

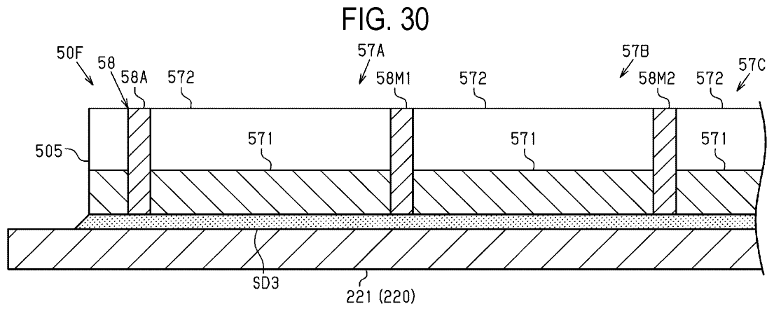

FIG. 28 is a schematic plan view showing the semiconductor device 20 according to the third embodiment. FIG. 29 is a schematic plan view showing the rectifier chip 50F of FIG. 28. FIG. 30 is a schematic cross-sectional view showing the rectifier chip of FIG. 29.

The semiconductor device 20 according to the third embodiment includes one rectifier chip 50F. The rectifier chip 50F according to the third embodiment has a rectangular shape in which a length in the X direction is longer than a length in the Y direction in a plan view. The rectifier chip 50F includes a chip top surface 501, a chip bottom surface 502, and plurality of chip side surfaces 503 to 506.

The rectifier chip 50F according to the third embodiment includes first to fourth chip regions 57A to 57D, an outer peripheral region 59, and an insulating region 58. The insulating region 58 is a region that partitions the first to fourth chip regions 57A to 57D in the rectifier chip 50F. As shown in FIG. 30, the insulating region 58 penetrates the rectifier chip 50F from the chip top surface 501 to the chip bottom surface 502 of the rectifier chip 50F. The insulating region 58 is made of an insulating material. In one example, the insulating region 58 is made of SiO₂. The insulating material that makes up the insulating region 58 can be changed as desired. The insulating region 58 may be made of a material containing SiN, a resin material having insulation property, or the like.

As shown in FIG. 29, the insulating region 58 includes first to fourth insulating regions 58A to 58D, which are frame-shaped in a plan view and surround the first to fourth chip regions 57A to 57D, respectively. In one example, the first to fourth insulating regions 58A to 58D may be rectangular frame-shaped in a plan view. In addition, the shape of each of the first to fourth insulating regions 58A to 58D in a plan view is not limited to a rectangular frame shape and can be changed as desired.

As shown in FIG. 29, the first insulating region 58A and the second insulating region 58B are integrated. As a result, the insulating region 58 includes a first intermediate insulating region 58M1 that serves as both the first insulating region 58A and the second insulating region 58B. Similarly, the second insulating region 58B and the third insulating region 58C are integrated. As a result, the insulating region 58 includes a second intermediate insulating region 58M2 that serves as both the second insulating region 58B and the third insulating region 58C. Further, the third insulating region 58C and the fourth insulating region 58D are integrated. As a result, the insulating region 58 includes a third intermediate insulating region 58M3 that serves as both the third insulating region 58C and the fourth insulating region 58D.

The first to fourth chip regions 57A to 57D are partitioned by the first to fourth insulating regions 58A to 58D, respectively. The first chip region 57A includes a plurality of input pads 53, a plurality of output pads 54, and a plurality of substrate connection pads 56. The plurality of substrate connection pads 56 may be omitted. Further, the first chip region 57A includes a circuit region 561 in which a rectifier circuit is formed. In other words, the first chip region 57A has the same configuration as that of the first rectifier chip 50A according to the second embodiment. Similarly, the second to fourth chip regions 57B to 57D have the same configurations as those of the second to fourth rectifier chips 50B to 50D according to the second embodiment, respectively.

FIG. 30 shows a schematic cross-sectional structure of the first chip region 57A and the second chip region 57B included in the rectifier chip 50F. The first chip region 57A includes a semiconductor substrate 571 and a semiconductor layer 572 on the semiconductor substrate 571. Similarly, the second chip region 57B includes a semiconductor substrate 571 and a semiconductor layer 572 on the semiconductor substrate 571.

Therefore, the semiconductor substrate 571 of the first chip region 57A is electrically insulated from the semiconductor substrate 571 of the second chip region 57B. Although not shown in the figure, the third and fourth chip regions 57C and 57D each include a semiconductor substrate 571, similar to the first and second chip regions 57A and 57B. The semiconductor substrates of the first to fourth chip regions 57A to 57D are electrically insulated from one another. That is, the first to fourth chip regions 57A to 57D have the same configurations as those of the first to fourth rectifier chips 50A to 50D according to the first embodiment, respectively. Therefore, it can be said that one rectifier chip 50 according to the third embodiment integrally includes the first to fourth rectifier chips 50A to 50D. Therefore, the insulation switch 120 according to the third embodiment can suppress occurrence of latch-up, similar to the insulation switch 100 according to the first embodiment.

The insulation switch 120 according to the third embodiment includes one rectifier chip 50. This one rectifier chip 50 includes the first to fourth chip regions 57A to 57D. The first to fourth chip regions 57A to 57D include first to fourth rectifier circuits 51A to 51D, respectively. The first to fourth rectifier circuits 51A to 51D drive first to fourth switch circuits 60A to 60D, respectively. As described above, the insulation switch 120 according to the third embodiment can drive the first to fourth switch circuits 60A to 60D by one rectifier chip 50. The one rectifier chip 50 is mounted on the second die pad 221. Therefore, the insulation switch 120 according to the third embodiment can easily form the semiconductor device 20 including the rectifier chip 50.

### Effects of Third Embodiment

The insulation switch 120 according to the third embodiment achieves effects set forth below.

(3-1) The insulation switch 120 includes one rectifier chip 50. The rectifier chip 50 includes the first to fourth chip regions 57A to 57D, the outer peripheral region 59, and the insulating region 58. The insulating region 58 is a region that partitions the first to fourth chip regions 57A to 57D in the rectifier chip 50. The first chip region 57A includes the semiconductor substrate 571 and the semiconductor layer 572 on the semiconductor substrate 571. Similarly, the second chip region 57B includes the semiconductor substrate 571 and the semiconductor layer 572 on the semiconductor substrate 571. The semiconductor substrate 571 of the first chip region 57A is electrically insulated from the semiconductor substrate 571 of the second chip region 57B. Therefore, the insulation switch 120 according to the third embodiment can suppress occurrence of latch-up, similar to the insulation switch 100 according to the first embodiment. Therefore, operations of the insulation switch 120 according to the third embodiment can be stabilized.

### Modification of Third Embodiment

The above-described third embodiment can be modified, for example, as follows. The above-described embodiment and the following modification can be combined with each other as long as no technical contradiction occurs. In the following modification, parts common to the above-described embodiment are denoted by the same reference numerals as in the above-described embodiment, and explanation thereof will be omitted.

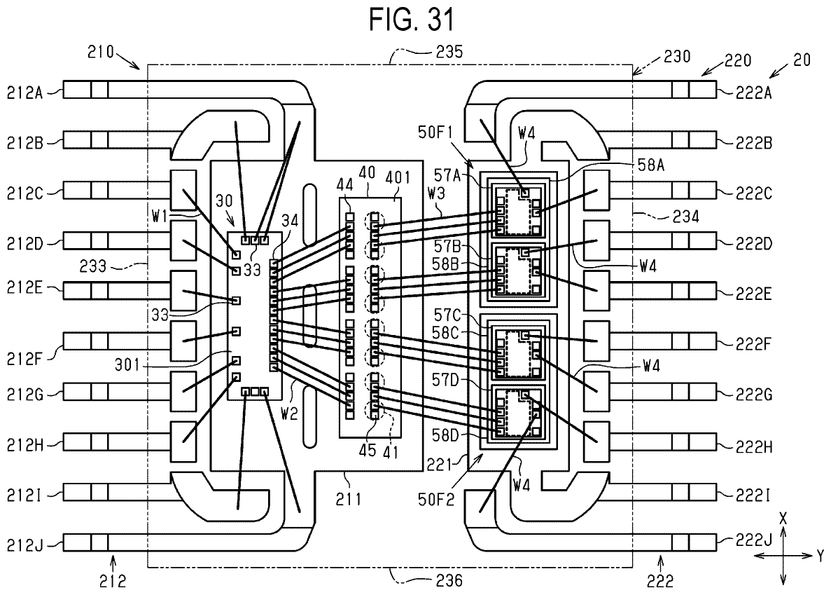

The number of chip regions included in the rectifier chip may be changed as appropriate. FIG. 31 is a schematic plan view showing a semiconductor device 20 according to a modification. The semiconductor device 20 of this modification includes a first rectifier chip 50F1 and a second rectifier chip 50F2.

The first rectifier chip 50F1 includes a first chip region 57A and a second chip region 57B. The first chip region 57A and the second chip region 57B are partitioned by a first insulating region 58A and a second insulating region 58B. The first chip region 57A and the second chip region 57B are insulated from each other by the first insulating region 58A and the second insulating region 58B. The second rectifier chip 50F2 includes a third chip region 57C and a fourth chip region 57D. The third chip region 57C and the fourth chip region 57D are partitioned by the third insulating region 58C and the fourth insulating region 58D. The third chip region 57C and the fourth chip region 57D are insulated from each other by the third insulating region 58C and the fourth insulating region 58D.

Operations of an insulation switch including the semiconductor device 20 according to this modification can be stabilized, similar to the insulation switch 120 according to the third embodiment.

### Fourth Embodiment

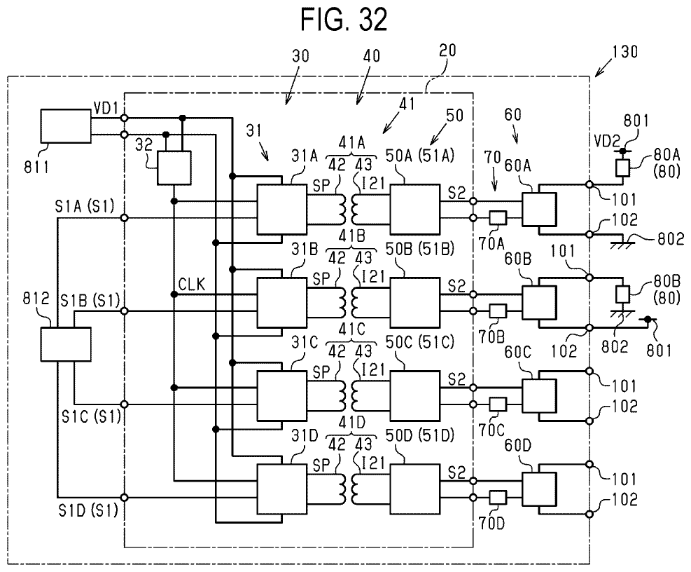

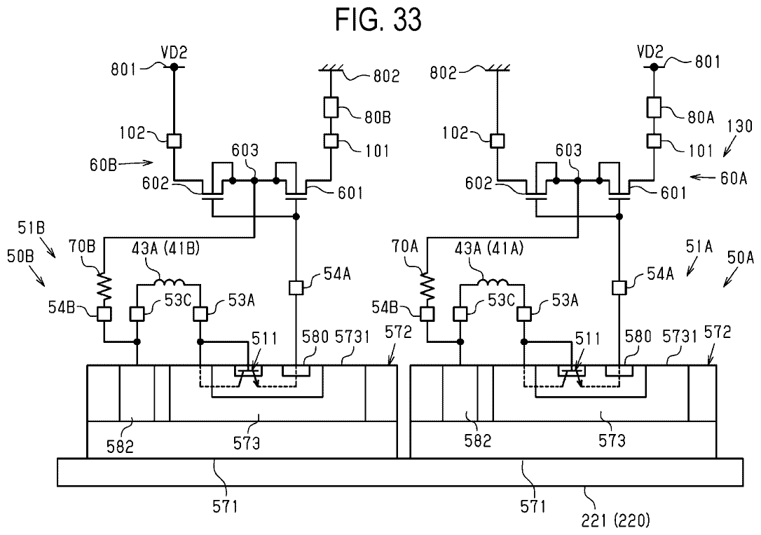

An insulation switch 130 according to a fourth embodiment will be described with reference to FIG. 32 and FIG. 33.

With respect to the insulation switch 130 according to the fourth embodiment, parts common to the insulation switch 100 according to the first embodiment, the insulation switch 110 according to the second embodiment, and the insulation switch 120 according to the third embodiment are denoted by the same reference numerals as in the above-described embodiments, and explanation thereof will be omitted.

FIG. 32 is a block diagram showing a schematic configuration of the insulation switch according to the fourth embodiment. FIG. 33 is an explanatory diagram showing the insulation switch of FIG. 32. In the insulation switch 130 according to the fourth embodiment, a plurality of resistors 70 are added to the insulation switch 100 according to the first embodiment.

The plurality of resistors 70 include first to fourth resistors 70A to 70D. The first to fourth resistors 70A to 70D are connected between the respective first to fourth switch circuits 60A to 60D and the semiconductor device 20.

The first resistor 70A is connected between the first rectifier circuit 51A of the semiconductor device 20 and the first switch circuit 60A. The first rectifier circuit 51A is included in the first rectifier chip 50A. The first rectifier chip 50A includes a first output pad 54A and a second output pad 54B. The first resistor 70A is connected between the second output pad 54B of the first rectifier chip 50A and the first switch circuit 60A.

The second resistor 70B is connected between the second rectifier circuit 51B of the semiconductor device 20 and the second switch circuit 60B. The second rectifier circuit 51B is included in the second rectifier chip 50B. The second rectifier chip 50B includes a first output pad 54A and a second output pad 54B. The second resistor 70B is connected between the second output pad 54B of the second rectifier chip 50B and the second switch circuit 60B.

The third resistor 70C is connected between the third rectifier circuit 51C of the semiconductor device 20 and the third switch circuit 60C. The third rectifier circuit 51C is included in the third rectifier chip 50C. The third rectifier chip 50C includes a first output pad 54A and a second output pad 54B. The third resistor 70C is connected between the second output pad 54B of the third rectifier chip 50C and the third switch circuit 60C.

The fourth resistor 70D is connected between the fourth rectifier circuit 51D of the semiconductor device 20 and the fourth switch circuit 60D. The fourth rectifier circuit 51D is included in the fourth rectifier chip 50D. The fourth rectifier chip 50D includes a first output pad 54A and a second output pad 54B. The fourth resistor 70D is connected between the second output pad 54B of the fourth rectifier chip 50D and the fourth switch circuit 60D.

Connection between the first and second switch circuits 60A and 60B and the first and second resistors 70A and 70B will be described in detail. The connection of the third and fourth resistors 70C and 70D is similar to that of the first and second resistors 70A and 70B, and thus a figure and explanation thereof are omitted.

As shown in FIG. 33, both the first switch circuit 60A and the second switch circuit 60B include a first switch element 601 and a second switch element 602. In one example, both the first switch element 601 and the second switch element 602 may be n-channel MOSFETs. The first switch element 601 and the second switch element 602 each include a source terminal, a drain terminal, a gate terminal, and a back gate terminal. The drain terminal of the first switch element 601 is connected to the first connection terminal 101, and the drain terminal of the second switch element 602 is connected to the second connection terminal 102.

The gate terminals of the first switch element 601 and the second switch element 602 of the first switch circuit 60A are connected to the first output pad 54A of the first rectifier chip 50A. A first terminal of the first resistor 70A is electrically connected to the second output pad 54B of the first rectifier chip 50A. A second terminal of the first resistor 70A is electrically connected to a node 603 between the source terminal of the first switch element 601 and the source terminal of the second switch element 602 of the first switch circuit 60A.

The gate terminals of the first switch element 601 and the second switch element 602 of the second switch circuit 60B are connected to the first output pad 54A of the second rectifier chip 50B. A first terminal of the second resistor 70B is electrically connected to the second output pad 54B of the second rectifier chip 50B. A second terminal of the first resistor 70A is electrically connected to a node 603 between the source terminal of the first switch element 601 and the source terminal of the second switch element 602 of the first switch circuit 60A.

The first resistor 70A may be provided as a current limiting resistor that limits a current between the first rectifier chip 50A and the first switch circuit 60A. A resistance value of the first resistor 70A may be 100Ω or more. Similarly, the second to fourth resistors 70B to 70D may be provided as current limiting resistors that limit currents between the second to fourth rectifier chips 50B to 50D and the second to fourth switch circuits 60B to 60D, respectively. Resistance values of the second to fourth resistors 70B to 70D may be 100Ω or more.

### Operation of Fourth Embodiment

As shown in FIG. 33, the first load 80A and the second load 80B are connected to the insulation switch 130 according to the fourth embodiment, similar to the insulation switch 100 according to the first embodiment.

When the first switch circuit 60A is turned on, a current flows from the high potential terminal 801 toward the low potential terminal 802 via the first load 80A and the first switch element 601 and the second switch element 602 of the first switch circuit 60A. The node 603 between the first switch element 601 and the second switch element 602 is connected to the second terminal of the first resistor 70A, and the first terminal of the first resistor 70A is connected to the second output pad 54B of the first rectifier chip 50A. A portion of the current flowing through the first load 80A flows from the node 603 toward the first rectifier chip 50A. The first resistor 70A limits the current flowing from the node 603 toward the first rectifier chip 50A.

The second output pad 54B of the first rectifier chip 50A is connected to the second semiconductor region 582. The second semiconductor region 582 is in contact with the semiconductor substrate 571. A current flowing toward the first rectifier chip 50A can be one of factors that cause voltage fluctuations in the semiconductor substrate 571. The first resistor 70A limits the current flowing toward the first rectifier chip 50A. The first resistor 70A further suppresses the voltage fluctuations in the semiconductor substrate 571 of the first rectifier chip 50A. Operations of the first rectifier chip 50A can be further stabilized by suppressing the voltage fluctuation in the semiconductor substrate 571.

When the second switch circuit 60B is turned on, a current flows from the high potential terminal 801 toward the low potential terminal 802 via the first switch element 601 and the second switch element 602 of the second switch circuit 60B and the second load 80B. The node 603 between the first switch element 601 and the second switch element 602 is connected to the second terminal of the second resistor 70B, and the first terminal of the second resistor 70B is connected to the second output pad 54B of the second rectifier chip 50B. A portion of the current flowing toward the second load 80B flows from the node 603 toward the second rectifier chip 50B. The second resistor 70B limits the current flowing from the node 603 toward the second rectifier chip 50B.

The second output pad 54B of the second rectifier chip 50B is connected to the second semiconductor region 582. The second semiconductor region 582 is in contact with the semiconductor substrate 571. A current flowing toward the second rectifier chip 50B can be one of factors that cause voltage fluctuations in the semiconductor substrate 571. The second resistor 70B limits the current flowing toward the second rectifier chip 50B. The second resistor 70B further suppresses the voltage fluctuations in the semiconductor substrate 571 of the second rectifier chip 50B. Operations of the second rectifier chip 50B can be further stabilized by suppressing the voltage fluctuation in the semiconductor substrate 571.

When the first load 80A or the second load 80B is connected to the third switch circuit 60C shown in FIG. 32, the third resistor 70C limits a current flowing toward the third rectifier chip 50C, like the first resistor 70A and the second resistor 70B. The third resistor 70C further suppresses the voltage fluctuations of the semiconductor substrate 571 of the third rectifier chip 50C. In addition, when the first load 80A or the second load 80B is connected to the fourth switch circuit 60D, the fourth resistor 70D limits a current flowing toward the fourth rectifier chip 50D, like the first resistor 70A and the second resistor 70B. The fourth resistor 70D further suppresses the voltage fluctuations of the semiconductor substrate 571 of the fourth rectifier chip 50D. Operations of the third and fourth rectifier chips 50C and 50D can be further stabilized by suppressing the voltage fluctuation of the semiconductor substrate 571 as described above.

As described above, the first resistor 70A limits the current flowing from the first switch circuit 60A to the first rectifier chip 50A. The second resistor 70B limits the current flowing from the second switch circuit 60B to the second rectifier chip 50B. For example, in a rectifier chip in which the semiconductor substrate 571 of the first rectifier chip 50A and the semiconductor substrate 571 of the second rectifier chip 50B are formed as a single semiconductor substrate, a parasitic transistor with the single semiconductor substrate serving as a base electrode is generated, as described in the comparative example in the first embodiment. The first resistor 70A and the second resistor 70B function as current limiting resistors that limit current flows to this parasitic transistor. As a result, in the rectifier chip including the single semiconductor substrate, the first resistor 70A and the second resistor 70B can suppress occurrence of latch-up.

### Effects of Fourth Embodiment

The insulation switch 130 according to the fourth embodiment achieves effects set forth below in addition to the effects of the insulation switch 100 according to the first embodiment.

(4-1) The insulation switch 130 according to the fourth embodiment includes the first resistor 70A electrically connected between the first rectifier chip 50A and the first switch circuit 60A. The first resistor 70A limits the current flowing from the first switch circuit 60A to the first rectifier chip 50A. As a result, operations of the first rectifier chip 50A can be further stabilized.

(4-2) The insulation switch 130 according to the fourth embodiment includes the second resistor 70B electrically connected between the second rectifier chip 50B and the second switch circuit 60B. The second resistor 70B limits the current flowing from the second switch circuit 60B to the second rectifier chip 50B. As a result, operations of the second rectifier chip 50B can be further stabilized.

(4-3) The insulation switch 130 according to the fourth embodiment includes the third resistor 70C electrically connected between the third rectifier chip 50C and the third switch circuit 60C. The third resistor 70C limits the current flowing from the third switch circuit 60C to the third rectifier chip 50C. As a result, operations of the third rectifier chip 50C can be further stabilized.

(4-4) The insulation switch 130 according to the fourth embodiment includes the fourth resistor 70D electrically connected between the fourth rectifier chip 50D and the fourth switch circuit 60D. The fourth resistor 70D limits the current flowing from the fourth switch circuit 60D to the fourth rectifier chip 50D. As a result, operations of the fourth rectifier chip 50D can be further stabilized.

### Modifications

The above-described embodiments and modifications can be modified, for example, as follows. The above-described embodiments and modifications and each of the following modifications can be combined with each other as long as no technical contradiction occurs. In the following modifications, parts common to the above-described embodiments are denoted by the same reference numerals as in the above-described embodiments, and explanation thereof will be omitted.

The configuration of the semiconductor device 20 may be modified as appropriate.

In the above-described embodiments, one transformer chip 40 is mounted, but a plurality of transformer chips may be mounted. For example, four transformer chips each including the first to fourth transformers 41A to 41D may be mounted. In addition, one transformer chip including the first transformer 41A and the second transformer 41B and one transformer chip including the third transformer 41C and the fourth transformer 41D may be mounted. Similarly, the configuration (number) of the pulse chips mounted on the semiconductor device may be changed.

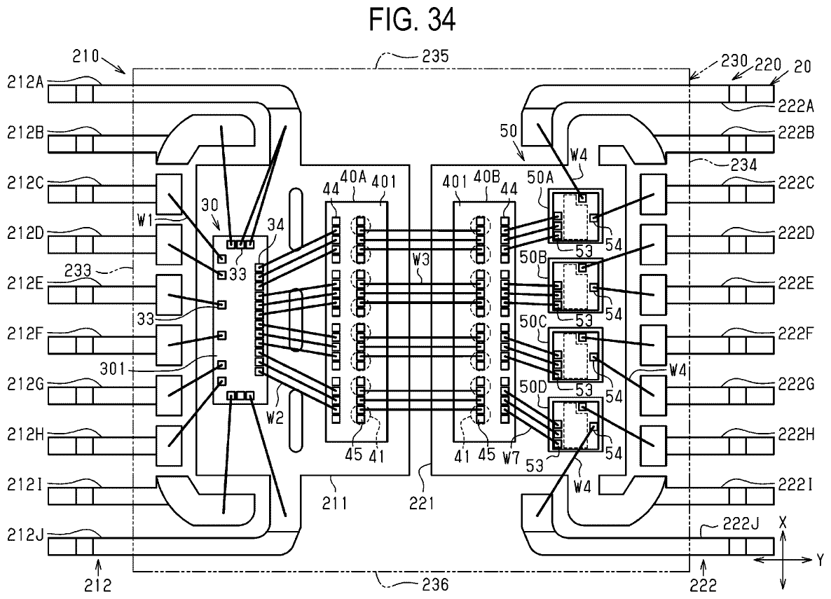

FIG. 34 is a schematic plan view showing a semiconductor device 20 according to a modification. The semiconductor device 20 according to this modification includes a first transformer chip 40A and a second transformer chip 40B. The first transformer chip 40A and the second transformer chip 40B may have the same configuration as the above-described transformer chip 40. The first transformer chip 40A and the second transformer chip 40B are disposed between the pulse chip 30 and the plurality of rectifier chips 50. The first transformer chip 40A is disposed to be closer to the pulse chip 30 than the second transformer chip 40B. The second transformer chip 40B is disposed to be closer to the plurality of rectifier chips 50 than the first transformer chip 40A. In one example, the pulse chip 30 and the first transformer chip 40A are mounted on the first die pad 211. The second transformer chip 40B and the plurality of rectifier chips 50 are mounted on the second die pad 221. The second transformer chip 40B may be mounted on the first die pad 211.

The second electrode pad 45 of the first transformer chip 40A is electrically connected to the second electrode pad 45 of the second transformer chip 40B by wires W3. The first electrode pad 44 of the second transformer chip 40B is electrically connected to the input pads 53 of the first to fourth rectifier chips 50A to 50D by wires W7. The semiconductor device 20 according to this modification can obtain the same effects as those of the first embodiment.

In contrast to the fourth embodiment, the resistors 70 (70A to 70D) may be provided inside the semiconductor device 20.

The first switch element 601 and the second switch element 602 may be p-channel MOSFETs. In this case, the gate terminals of the first switch element 601 and the second switch element 602 are connected to the second output pad 54B, and the drain terminals of the first switch element 601 and the second switch element 602 are connected to each other and to the first output pad 54A.

The term “on” as used in the present disclosure includes the meanings of “on” and “above” unless clearly stated otherwise in the context. Therefore, the expression “a first layer is formed on a second layer” is intended that in some embodiments, the first layer can be directly disposed on the second layer and in contact with the second layer, while in other embodiments, the first layer can be disposed above the second layer without contacting the second layer. That is, the term “on” does not exclude a structure in which other layers are formed between the first and second layers.

The Z direction used in the present disclosure does not necessarily have to be the vertical direction, and it does not have to be exactly the same as the vertical direction. Therefore, in various structures (for example, the structure shown in FIG. 1) according to the present disclosure, “up” and “down” in the Z-axis direction are not limited to “up” and “down” in the vertical direction. For example, the X-axis direction may be the vertical direction, or the Y-axis direction may be the vertical direction.

### SUPPLEMENTARY NOTES

The technical ideas that can be recognized from the above-described embodiments are described below. In addition, for the purpose of aiding understanding and not for the purpose of limitation, components described in supplementary notes are labeled with the reference numerals of the corresponding components in the embodiments. The reference numerals are provided as examples to aid understanding, and the components described in supplementary notes should not be limited to the components indicated by the reference numerals.

### Supplementary Note 1

A semiconductor device including:
a first transformer (41A) including a primary coil (42) and a secondary coil (43);
a second transformer (41B) including a primary coil (42) and a secondary coil (43);
a first rectifier chip (50A) including a first rectifier circuit that is electrically connected to the secondary coil (43) of the first transformer (41A) and controls a first switch circuit (60A) by rectifying an induced current (121) flowing through the secondary coil (43) of the first transformer (41A);
a second rectifier chip (50B) including a second rectifier circuit that is electrically connected to the secondary coil (43) of the second transformer (41B) and controls a second switch circuit (60B) by rectifying an induced current (122) flowing through the secondary coil (43) of the second transformer (41B); and
a first frame (221) on which the first rectifier chip (50A) and the second rectifier chip (50B) are mounted,
wherein each of the first rectifier chip (50A) and the second rectifier chip (50B) includes:
   a first output pad (54A) and a second output pad (54B);
   a semiconductor substrate (571) of a first conductivity type including a first surface;
   a first semiconductor region (573) of a second conductivity type disposed on the first surface;
   a first transistor (511) provided in the first semiconductor region (573) and electrically connected to the first output pad (54A); and
   a second semiconductor region (582) of the second conductivity type provided at a position spaced apart from the first transistor (511) in the first semiconductor region (573) and electrically connected to the second output pad (54B),
wherein the second semiconductor region (582) is in contact with the semiconductor substrate (571), and
wherein the first rectifier chip (50A) and the second rectifier chip (50B) are disposed to be spaced apart from each other.

### Supplementary Note 2

The semiconductor device of Supplementary Note 1, wherein the first transistor (511) includes:
a base region (578) of the first conductivity type provided on a surface of the first semiconductor region (573);
an emitter region (580) of the second conductivity type provided in the base region (578); and
a collector region (573) of the second conductivity type provided in the first semiconductor region (573),
wherein the first output pad (54A) and the emitter region (580) are electrically connected to each other.

### Supplementary Note 3

The semiconductor device of Supplementary Note 1 or 2, further including:
a second frame (211) disposed to be spaced apart from the first frame (221) in a first direction (Y) in a plan view; and
a transformer chip (40) mounted on the second frame (211) and including the first transformer (41A) and the second transformer (41B).

### Supplementary Note 4

The semiconductor device of Supplementary Note 3, wherein the first transformer (41A) and the second transformer (41B) are arranged to be spaced apart from each other in a second direction (X) intersecting the first direction (Y) in a plan view, and
wherein the first rectifier chip (50A) and the second rectifier chip (50B) are arranged to be spaced apart from each other in the second direction (X) in a plan view.

### Supplementary Note 5

The semiconductor device of Supplementary Note 4, wherein each of the first rectifier chip (50A) and the second rectifier chip (50B) includes
a first main surface (501) having a circuit region (561) in which the first transistor (511) is disposed; and
a plurality of substrate connection pads (56) provided on the first main surface (501) and electrically connected to the semiconductor substrate (571),
wherein the plurality of substrate connection pads (56) include a first substrate connection pad (56A) and a second substrate connection pad (56B), and
wherein the first substrate connection pad (56A) and the second substrate connection pad (56B) are disposed with the circuit region (561) interposed between the first substrate connection pad (56A) and the second substrate connection pad (56B) in the first direction (Y).

### Supplementary Note 6

The semiconductor device of Supplementary Note 5, wherein a portion of the circuit region (561) is recessed, and the first output pad (54A) is disposed in the recessed space.

### Supplementary Note 7

The semiconductor device of Supplementary Note 5 or 6, wherein the first substrate connection pad (56A) and the second substrate connection pad (56B) are disposed offset from each other in the second direction (X).

### Supplementary Note 8

The semiconductor device of any one of Supplementary Notes 5 to 7, wherein the first main surface (501) is rectangular in a plan view, and
wherein the first substrate connection pad (56A) and the second substrate connection pad (56B) are disposed diagonally to each other on the first main surface (501).

### Supplementary Note 9

The semiconductor device of any one of Supplementary Notes 5 to 8, wherein the plurality of substrate connection pads (56) include a third substrate connection pad (56C) disposed to be spaced apart from the second substrate connection pad (56B) in the second direction (X).

### Supplementary Note 10

The semiconductor device of Supplementary Note 9, wherein the second output pad (54B) of the first rectifier chip (50A) is disposed between the third substrate connection pad (56C) and the second substrate connection pad (56B).

### Supplementary Note 11

The semiconductor device of Supplementary Note 9 or 10, wherein the third substrate connection pad (56C) and the first output pad (54A) are disposed offset from each other in the first direction (Y).

### Supplementary Note 12

The semiconductor device of any one of Supplementary Notes 9 to 11, wherein each of the first rectifier chip (50A) and the second rectifier chip (50B) includes a plurality of input pads (53) connected to the secondary coil (43),
wherein the plurality of input pads (53) are arranged on an opposite side of the first output pad (54A) and the second output pad (54B) with respect to the circuit region (561), and
wherein the first substrate connection pad (56A) is disposed in line with the plurality of input pads (53) in the second direction (X).

### Supplementary Note 13

The semiconductor device of Supplementary Note 12, wherein the plurality of input pads (53) include an input pad (53C) electrically connected to the second output pad (54B).

### Supplementary Note 14

The semiconductor device of Supplementary Note 12, wherein the plurality of input pads (53) include first to third input pads (53A to 53C), and
wherein the secondary coil (43) includes:
   a first coil (43A) connected between the first input pad (53A) and the third input pad (53C); and
   a second coil (43B) connected between the second input pad (53B) and the third input pad (53C).

### Supplementary Note 15

The semiconductor device of Supplementary Note 14, wherein the third input pad (53C) is electrically connected to the second output pad (54B).

### Supplementary Note 16

The semiconductor device of any one of Supplementary Notes 9 to 15, further including:
a wire (W5A) connecting the second substrate connection pad (56B) of the first rectifier chip (50A) and the first substrate connection pad (56A) of the second rectifier chip (50B).

### Supplementary Note 17

The semiconductor device of any one of Supplementary Notes 9 to 16, further including:
a plurality of first leads (222) arranged along the second direction (X) on an opposite side of the transformer chip (40) with respect to the first rectifier chip (50A) and the second rectifier chip (50B).

### Supplementary Note 18

The semiconductor device of Supplementary Note 17, wherein the first output pad (54A) and the second output pad (54B) of the first rectifier chip (50A) and the first output pad (54A) and the second output pad (54B) of the second rectifier chip (50B) are connected to different first leads (222) among the plurality of first leads (222) by wires (W4), respectively.

### Supplementary Note 19

The semiconductor device of Supplementary Note 18, wherein a plurality of rectifier chips (50) including the first rectifier chip (50A) and the second rectifier chip (50B) are arranged in the second direction (X), and the first rectifier chip (50A, 50D) is disposed at a first end of the plurality of rectifier chips, and
wherein the third substrate connection pad (56C) of the first rectifier chip (50A, 50D) is connected to a first lead (222B, 222I), among the plurality of first leads (222), which is different from the first leads to which the first output pad (54A) and the second output pad (54B) are respectively connected.

### Supplementary Note 20

The semiconductor device of Supplementary Note 19, wherein any one among the first substrate connection pad (56A), the second substrate connection pad (56B), and the third substrate connection pad (56C) is connected to the first lead to which the first output pad (54A) is connected.

### Supplementary Note 21

The semiconductor device of Supplementary Note 19, wherein any one of the first substrate connection pad (56A), the second substrate connection pad (56B), and the third substrate connection pad (56C) is connected to the first lead to which the second output pad (54B) is connected.

### Supplementary Note 22

The semiconductor device of any one of Supplementary Notes 3 to 21, further including:
a capacitor (541) connected to the emitter region (580) of the first transistor (511).

### Supplementary Note 23

The semiconductor device of any one of Supplementary Notes 3 to 22, wherein the first transistor (511, 512) and the capacitor (541, 542) are provided in plurality and are connected in series.

### Supplementary Note 24

A semiconductor device including:
a first transformer (41A) including a primary coil (42) and a secondary coil (43);
a second transformer (41B) including a primary coil (42) and a secondary coil (43);
a rectifier chip connected to the secondary coil (43) of the first transformer (41A) and the secondary coil (43) of the second transformer (41B); and
a first frame (221) on which the rectifier chip (50) is mounted,
wherein the rectifier chip (50) includes:
   a first rectification region including a first rectifier circuit that is electrically connected to the secondary coil (43) of the first transformer (41A) and controls a first switch circuit (60A) by rectifying an induced current (121) flowing through the secondary coil (43) of the first transformer (41A); and
   a second rectification region including a second rectifier circuit that is electrically connected to the secondary coil (43) of the second transformer (41B) and controls a second switch circuit (60B) by rectifying an induced current (122) flowing through the secondary coil (43) of the second transformer (41B), wherein each of the first rectification region and the second rectification region includes:
   a first output pad (54A) and a second output pad (54B);
   a semiconductor substrate (571) of a first conductivity type including a first surface;
   a first semiconductor region (573) of a second conductivity type disposed on the first surface;
   a first transistor (511) provided in the first semiconductor region (573) and electrically connected to the first output pad (54A); and
   a second semiconductor region (582) of the second conductivity type provided at a position spaced apart from the first transistor (511) in the first semiconductor region (573)
and electrically connected to the second output pad (54B),
wherein the second semiconductor region (582) is in contact with the semiconductor substrate (571), and
wherein the rectifier chip includes an insulating region that insulates the semiconductor substrate (571) of the first rectification region from the semiconductor substrate (571) of the second rectification region.

### Supplementary Note 25

An insulation switch including:
a semiconductor device including a first rectifier chip (50A) and a second rectifier chip (50B);
a first switch circuit (60A) electrically connected to the first rectifier chip (50A); and
a second switch circuit (60B) electrically connected to the second rectifier chip (50B),
wherein the semiconductor device includes:
   a first transformer (41A) including a primary coil (42) and a secondary coil (43);
   a second transformer (41B) including a primary coil (42) and a secondary coil (43);
   the first rectifier chip (50A) including a first rectifier circuit that is electrically connected to the secondary coil (43) of the first transformer (41A) and controls the first switch circuit (60A) by rectifying an induced current (121) flowing through the secondary coil (43) of the first transformer (41A);
   the second rectifier chip (50B) including a second rectifier circuit that is electrically connected to the secondary coil (43) of the second transformer (41B) and controls the second switch circuit (60B) by rectifying an induced current (122) flowing through the secondary coil (43) of the second transformer (41B); and
   a first frame (221) on which the first rectifier chip (50A) and the second rectifier chip (50B) are mounted, wherein each of the first rectifier chip (50A) and the second rectifier chip (50B) includes:
   a first output pad (54A) and a second output pad (54B);
   a semiconductor substrate (571) of a first conductivity type including a first surface;
   a first semiconductor region (573) of a second conductivity type disposed on the first surface;
   a first transistor (511) provided in the first semiconductor region (573) and electrically connected to the first output pad (54A); and
   a second semiconductor region (582) of the second conductivity type provided at a position spaced apart from the first transistor (511) in the first semiconductor region (573) and electrically connected to the second output pad (54B),
wherein the second semiconductor region (582) is in contact with the semiconductor substrate (571), and
wherein the first rectifier chip (50A) and the second rectifier chip (50B) are disposed to be spaced apart from each other.

### Supplementary Note 26

The insulation switch of Supplementary Note 25, wherein each of the first switch circuit (60A) and the second switch circuit (60B) includes a first switch element (601) and a second switch element (602), which are connected in series.

### Supplementary Note 27

The insulation switch of Supplementary Note 26, wherein the first switch element (601) and the second switch element (602) are n-channel MOSFETs.

### Supplementary Note 28

The insulation switch of Supplementary Note 26, wherein the first switch element (601) and the second switch element (602) are p-channel MOSFETs.

### Supplementary Note 29

The insulation switch of any one of Supplementary Notes 26 to 28, further including:
a first resistor (70A) electrically connected between the first rectifier chip (50A) and the first switch circuit (60A); and
a second resistor (70B) electrically connected between the second rectifier chip (50B) and the second switch circuit (60B).

### Supplementary Note 30

The insulation switch of Supplementary Note 29, wherein the first resistor (70A) is connected between a connection point (603) between the first switch element (601) and the second switch element (602) and the second output pad (54B), and
wherein the second resistor (70B) is connected between a connection point (603) between the first switch element (601) and the second switch element (602) and the second output pad (54B).

### Supplementary Note 31

The insulation switch of any one of Supplementary Notes 25 to 30, further including:
a second frame (211) disposed to be spaced apart from the first frame (221) in a first direction (Y) in a plan view; and
a transformer chip (40) mounted on the second frame (211) and including the first transformer (41A) and the second transformer (41B).

### Supplementary Note 32

The insulation switch of Supplementary Note 31, further including:
a pulse chip (30) disposed on an opposite side of the first rectifier chip (50A) and the second rectifier chip (50B) with respect to the transformer chip (40),
wherein the pulse chip (30) includes:
   a first pulse generation circuit (31A) connected to the primary coil (42) of the first transformer (41A); and
   a second pulse generation circuit (31B) connected to the primary coil (42) of the second transformer (41B).

### Supplementary Note 33

The insulation switch of Supplementary Note 32, wherein the pulse chip (30) is mounted on the second frame (211).

### Supplementary Note 34

A rectifier chip (50) including a rectifier circuit for use in controlling a switch circuit (60) by rectifying an induced current flowing through a transformer (41), including:
a first output pad (54A) and a second output pad (54B);
a semiconductor substrate (571) of a first conductivity type including a first surface;
a first semiconductor region (573) of a second conductivity type disposed on the first surface;
a first transistor (511) provided in the first semiconductor region (573) and electrically connected to the first output pad (54A);
a second semiconductor region (582) of the second conductivity type provided at a position spaced apart from the first transistor (511) in the first semiconductor region (573), electrically connected to the second output pad (54B), and in contact with the semiconductor substrate (571);
a first main surface (501) including a circuit region (561) in which the first transistor (511) is disposed; and
a plurality of substrate connection pads (56) provided on the first main surface (501) and electrically connected to the semiconductor substrate (571),
wherein the plurality of substrate connection pads (56) include a first substrate connection pad (56A) and a second substrate connection pad (56B), which are provided on both sides of the circuit region (561) in a first direction (Y) in a plan view.

The above description is merely an example. Those skilled in the art will appreciate that more possible combinations and substitutions are possible beyond the components and methods (manufacturing processes) listed for the purposes of illustrating the techniques of the present disclosure. The present disclosure is intended to cover all alternatives, modifications, and changes that fall within the scope of the present disclosure, including the claims.

While certain embodiments have been described, these embodiments have been presented by way of example only and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device comprising:
a first transformer including a primary coil and a secondary coil;
a second transformer including a primary coil and a secondary coil;
a first rectifier chip including a first rectifier circuit that is electrically connected to the secondary coil of the first transformer and controls a first switch circuit by rectifying an induced current flowing through the secondary coil of the first transformer;
a second rectifier chip including a second rectifier circuit that is electrically connected to the secondary coil of the second transformer and controls a second switch circuit by rectifying an induced current flowing through the secondary coil of the second transformer; and
a first frame on which the first rectifier chip and the second rectifier chip are mounted,
wherein each of the first rectifier chip and the second rectifier chip includes:
a first output pad and a second output pad;
a semiconductor substrate of a first conductivity type including a first surface;
a first semiconductor region of a second conductivity type disposed on the first surface;
a first transistor provided in the first semiconductor region and electrically connected to the first output pad; and
a second semiconductor region of the second conductivity type provided at a position spaced apart from the first transistor in the first semiconductor region and electrically connected to the second output pad,
wherein the second semiconductor region is in contact with the semiconductor substrate, and
wherein the first rectifier chip and the second rectifier chip are disposed to be spaced apart from each other.

2. The semiconductor device of claim 1, wherein the first transistor includes:
a base region of the first conductivity type provided on a surface of the first semiconductor region;
an emitter region of the second conductivity type provided in the base region; and
a collector region of the second conductivity type provided in the first semiconductor region,
wherein the first output pad and the emitter region are electrically connected to each other.

3. The semiconductor device of claim 1, further comprising:
a second frame disposed to be spaced apart from the first frame in a first direction in a plan view; and
a transformer chip mounted on the second frame and including the first transformer and the second transformer.

4. The semiconductor device of claim 3, wherein the first transformer and the second transformer are arranged to be spaced apart from each other in a second direction intersecting the first direction in a plan view, and
wherein the first rectifier chip and the second rectifier chip are arranged to be spaced apart from each other in the second direction in a plan view.

5. The semiconductor device of claim 4, wherein each of the first rectifier chip and the second rectifier chip includes:
a first main surface having a circuit region in which the first transistor is disposed; and
a plurality of substrate connection pads provided on the first main surface and electrically connected to the semiconductor substrate,
wherein the plurality of substrate connection pads include a first substrate connection pad and a second substrate connection pad, and
wherein the first substrate connection pad and the second substrate connection pad are disposed with the circuit region interposed between the first substrate connection pad and the second substrate connection pad in the first direction.

6. The semiconductor device of claim 5, wherein a portion of the circuit region is recessed, and the first output pad is disposed in the recessed space.

7. The semiconductor device of claim 5, wherein the first substrate connection pad and the second substrate connection pad are disposed offset from each other in the second direction.

8. The semiconductor device of claim 5, wherein the first main surface is rectangular in a plan view, and the first substrate connection pad and the second substrate connection pad are disposed diagonally to each other on the first main surface.

9. The semiconductor device of claim 5, wherein the plurality of substrate connection pads includes a third substrate connection pad disposed to be spaced apart from the second substrate connection pad in the second direction.

10. The semiconductor device of claim 9, wherein the second output pad of the first rectifier chip is disposed between the third substrate connection pad and the second substrate connection pad.

11. The semiconductor device of claim 9, wherein the third substrate connection pad and the first output pad are disposed offset from each other in the first direction.

12. The semiconductor device of claim 9, wherein each of the first rectifier chip and the second rectifier chip includes a plurality of input pads connected to the secondary coil,
wherein the plurality of input pads is disposed on an opposite side of the first output pad and the second output pad with respect to the circuit region, and
wherein the first substrate connection pad is arranged in line with the plurality of input pads in the second direction.

13. The semiconductor device of claim 12, wherein the plurality of input pads includes an input pad electrically connected to the second output pad.

14. The semiconductor device of claim 12, wherein the plurality of input pads includes first to third input pads, and
wherein the secondary coil includes:
a first coil connected between the first input pad and the third input pad; and
a second coil connected between the second input pad and the third input pad.

15. The semiconductor device of claim 14, wherein the third input pad is electrically connected to the second output pad.

16. The semiconductor device of claim 9, further comprising:
a wire connecting the second substrate connection pad of the first rectifier chip and the first substrate connection pad of the second rectifier chip.

17. The semiconductor device of claim 9, further comprising:
a plurality of first leads arranged along the second direction on an opposite side of the transformer chip with respect to the first rectifier chip and the second rectifier chip.

18. The semiconductor device of claim 17, wherein the first output pad and the second output pad of the first rectifier chip and the first output pad and the second output pad of the second rectifier chip are connected to different first leads among the plurality of first leads by wires, respectively.

19. The semiconductor device of claim 18, wherein a plurality of rectifier chips including the first rectifier chip and the second rectifier chip are arranged in the second direction, and the first rectifier chip is disposed at a first end of the plurality of rectifier chips, and
wherein the third substrate connection pad of the first rectifier chip is connected to a first lead, among the plurality of first leads, which is different from the first leads to which the first output pad and the second output pad are respectively connected.

20. An insulation switch comprising:
a semiconductor device including a first rectifier chip and a second rectifier chip;
a first switch circuit electrically connected to the first rectifier chip; and
a second switch circuit electrically connected to the second rectifier chip,
wherein the semiconductor device includes:
a first transformer including a primary coil and a secondary coil;
a second transformer including a primary coil and a secondary coil;
the first rectifier chip including a first rectifier circuit that is electrically connected to the secondary coil of the first transformer and controls the first switch circuit by rectifying an induced current flowing through the secondary coil of the first transformer;
the second rectifier chip including a second rectifier circuit that is electrically connected to the secondary coil of the second transformer and controls the second switch circuit by rectifying an induced current flowing through the secondary coil of the second transformer; and
a first frame on which the first rectifier chip and the second rectifier chip are mounted,
wherein each of the first rectifier chip and the second rectifier chip includes:
a first output pad and a second output pad;
a semiconductor substrate of a first conductivity type including a first surface;
a first semiconductor region of a second conductivity type disposed on the first surface;
a first transistor provided in the first semiconductor region and electrically connected to the first output pad; and
a second semiconductor region of the second conductivity type provided at a position spaced apart from the first transistor in the first semiconductor region and electrically connected to the second output pad,
wherein the second semiconductor region is in contact with the semiconductor substrate, and
wherein the first rectifier chip and the second rectifier chip are disposed to be spaced apart from each other.
